(19) United States
(12) Patent Application Publication
(10) Pub. No.: US 2025/0176223 A1
(43) Pub. Date: May 29, 2025

(54) SEMICONDUCTOR DEVICE

(71) Applicant: Samsung Electronics Co., Ltd., Suwon-si (KR)

(72) Inventors: Jeewoong KIM, Suwon-si (KR); Yunsuk NAM, Suwon-si (KR); Jaehoon SHIN, Suwon-si (KR); Jinkyu KIM, Suwon-si (KR); Jaehyun AHN, Suwon-si (KR); Darong OH, Suwon-si (KR)

(73) Assignee: Samsung Electronics Co., Ltd., Suwon-si (KR)

(21) Appl. No.: 18/739,869

(22) Filed: Jun. 11, 2024

(30) Foreign Application Priority Data
Nov. 28, 2023 (KR) 10-2023-0167857

(51) Int. Cl. H01L 29/786; H01L 21/8234; H01L 27/088; H01L 29/06; H01L 29/08; H01L 29/423; H01L 29/66; H01L 29/775

(52) U.S. Cl. CPC H10D 30/6757; H10D 30/014; H10D 30/43; H10D 30/6735; H10D 62/121; H10D 62/151; H10D 64/018; H10D 84/0135; H10D 84/0149; H10D 84/038; H10D 84/83

(57) ABSTRACT

A semiconductor device may include a substrate including an insulating structure, a back-side metal layer below the substrate, a source/drain pattern on the insulating structure, a channel pattern connected to the source/drain pattern and including semiconductor patterns vertically stacked and spaced apart from each other, a gate electrode on the semiconductor patterns, and a back-side gate contact penetrating the substrate and electrically connecting the back-side metal layer to the gate electrode. The gate electrode may include inner electrodes between adjacent ones of the semiconductor patterns and an outer electrode on the uppermost one of the semiconductor patterns. A first surface of the back-side gate contact may be in contact with a bottom surface of the gate electrode, and a second surface of the back-side gate contact may be in contact with a side of the insulating structure. An angle between the first and second surfaces may be an acute angle.

### CROSS-REFERENCE TO RELATED APPLICATIONS

This U.S. non-provisional patent application claims priority under 35 U.S.C. § 119 to Korean Patent Application No. 10-2023-0167857, filed on Nov. 28, 2023, in the Korean Intellectual Property Office, the entire contents of which are hereby incorporated by reference.

### BACKGROUND

The present disclosure relates to a semiconductor device, and in particular, to a semiconductor device including a field effect transistor.

A semiconductor device includes an integrated circuit consisting of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize high performance semiconductor devices.

### SUMMARY

An embodiment of inventive concepts provides a semiconductor device with improved reliability.

An embodiment of inventive concepts provides a semiconductor device with improved electrical characteristics.

According to an embodiment of inventive concepts, a semiconductor device may include a substrate including an insulating structure; a back-side metal layer below the substrate; a source/drain pattern on the insulating structure; a channel pattern connected to the source/drain pattern, the channel pattern including a plurality of semiconductor patterns, which may be vertically stacked and spaced apart from each other; a gate electrode on the plurality of semiconductor patterns, the gate electrode including inner electrodes and an outer electrode, the inner electrodes being between adjacent ones of the plurality of semiconductor patterns, and the outer electrode being on an uppermost one of the semiconductor patterns; and a back-side gate contact penetrating the substrate and electrically connecting the back-side metal layer to the gate electrode. The back-side gate contact may include a first surface and a second surface. The first surface of the back-side gate contact may be in contact with a bottom surface of the gate electrode. The second surface of the back-side gate contact may be in contact with a side surface of the insulating structure. An angle between the first surface of the back-side gate contact and the second surface of the back-side gate contact may be an acute angle.

According to an embodiment of inventive concepts, a semiconductor device may include a substrate including a plurality of insulating structures; a back-side metal layer below the substrate; a source/drain pattern on each of the plurality of insulating structures; a channel pattern connected to the source/drain pattern, the channel pattern including a first semiconductor pattern, a second semiconductor pattern, and a third semiconductor pattern, which may be vertically stacked and spaced apart from each other; a gate electrode on the first semiconductor pattern to the third semiconductor pattern; an inner spacer separating the source/drain pattern and the gate electrode from each other; a back-side gate contact penetrating the substrate and extending between the plurality of insulating structures; and an air gap pattern between the back-side gate contact and the inner spacer. The gate electrode may include a first inner electrode, a second inner electrode, and a third inner electrode, the second inner electrode and the third inner electrode being between adjacent semiconductor patterns among the first semiconductor pattern, the second semiconductor pattern, and the third semiconductor pattern. The gate electrode may include an outer electrode on the third semiconductor pattern. The air gap pattern may be enclosed by the insulating structure, the inner spacer, the first inner electrode, and the back-side gate contact.

According to an embodiment of inventive concepts, a semiconductor device may include a substrate including a plurality of insulating structures; a source/drain pattern on each of the insulating structures; a channel pattern connected to the source/drain pattern, the channel pattern including a plurality of semiconductor patterns, which may be stacked and spaced apart from each other; a gate electrode on the channel pattern; a gate insulating layer between the gate electrode and the channel pattern; a gate spacer on a side surface of the gate electrode; a first interlayer insulating layer covering the source/drain pattern and the gate electrode; an active contact penetrating the first interlayer insulating layer, the active contact being electrically connected to the source/drain pattern; a first metal layer on the first interlayer insulating layer, the first metal layer including a first interconnection line electrically connected to the active contact; a second metal layer on the first metal layer, the second metal layer including a second interconnection line electrically connected to the first metal layer; a back-side metal layer below the substrate; and a back-side gate contact penetrating the substrate and electrically connecting the back-side metal layer to the gate electrode. The gate electrode may include a first inner electrode, a second inner electrode, and a third inner electrode, the second inner electrode and the third inner electrode being between adjacent semiconductor patterns among the plurality of semiconductor patterns. The gate electrode may include an outer electrode on an uppermost one of the plurality of semiconductor patterns. The first inner electrode may have a first thickness. The second inner electrode may have a second thickness. The third inner electrode may have a third thickness, and the outer electrode may have a fourth thickness. The first thickness may be equal to or larger than the fourth thickness.

### BRIEF DESCRIPTION OF THE DRAWINGS

FIGS. 1 to 3 are conceptual diagrams illustrating logic cells of a semiconductor device according to an embodiment of inventive concepts.

FIG. 4 is a plan view illustrating a semiconductor device according to an embodiment of inventive concepts.

FIGS. 5A to 5D are sectional views taken along lines A-A′, B-B′, C-C′, and D-D′, respectively, of FIG. 4.

FIG. 6A is an enlarged sectional view illustrating a portion ‘M’ of FIG. 5A. FIGS. 6B and 6C are enlarged sectional views illustrating the portion ‘M’ of FIG. 5A according to some embodiments of inventive concepts.

FIGS. 7 and 8 are sectional views illustrating other examples of the structure shown in FIG. 5A.

FIGS. 9A to 20D are sectional views illustrating a method of fabricating a semiconductor device according to an embodiment of inventive concepts.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%. While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

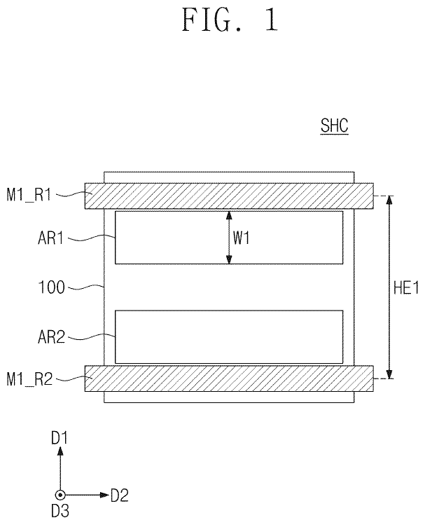

FIGS. 1 to 3 are conceptual diagrams illustrating logic cells of a semiconductor device according to an embodiment of inventive concepts.

Referring to FIG. 1, a single height cell SHC may be provided. In detail, a first power line M1_R1 and a second power line M1_R2 may be provided on a substrate 100. The first power line M1_R1 may be a conduction path, to which a source voltage VSS (e.g., a ground voltage) is provided. The second power line M1_R2 may be a conduction path, to which a drain voltage VDD (e.g., a power voltage) is provided.

The single height cell SHC may be defined between the first power line M1_R1 and the second power line M1_R2. The single height cell SHC may include one first active region AR1 and one second active region AR2. One of the first and second active regions AR1 and AR2 may be a PMOSFET region, and the other may be an NMOSFET region. That is, the single height cell SHC may have a CMOS structure provided between the first and second power lines M1_R1 and M1_R2.

Each of the first and second active regions AR1 and AR2 may have an active width W1 in a first direction D1. A length of the single height cell SHC in the first direction D1 may be defined as a single height cell height HE1. The single height cell height HE1 may be substantially equal to a distance (e.g., pitch) between the first and second power lines M1_R1 and M1_R2.

The single height cell SHC may constitute a single logic cell. In the present specification, the logic cell may mean a logic device (e.g., AND, OR, XOR, XNOR, inverter, and so forth) that is configured to execute a specific function. In other words, the logic cell may include transistors constituting the logic device and interconnection lines connecting the transistors to each other.

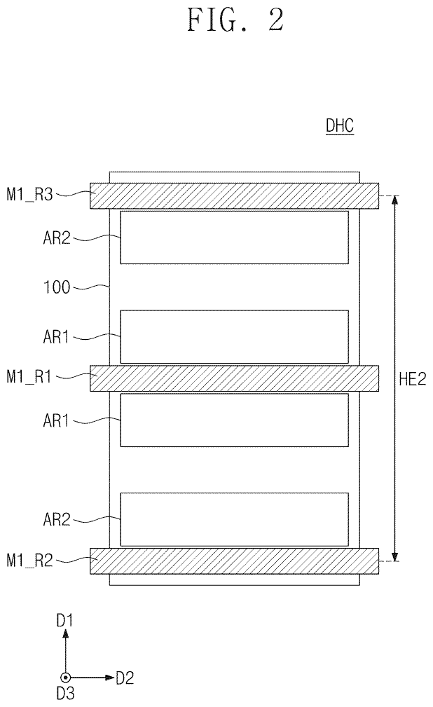

Referring to FIG. 2, a double height cell DHC may be provided. In detail, the first power line M1_R1, the second power line M1_R2, and a third power line M1_R3 may be provided on the substrate 100. The first power line M1_R1 may be disposed between the second power line M1_R2 and the third power line M1_R3. The third power line M1_R3 may be a conduction path, to which the source voltage VSS is provided.

The double height cell DHC may be defined between the second power line M1_R2 and the third power line M1_R3. The double height cell DHC may include a pair of first active regions AR1 and a pair of second active regions AR2.

One of the paired second active regions AR2 may be adjacent to the second power line M1_R2. The other of the paired second active regions AR2 may be adjacent to the third power line M1_R3. The paired first active regions AR1 may be adjacent to the first power line M1_R1. When viewed in a plan view, the first power line M1_R1 may be disposed between the paired first active regions AR1.

A length of the double height cell DHC in the first direction D1 may be defined as a double height cell height HE2. The double height cell height HE2 may be about two times the single height cell height HE1 of FIG. 1. The paired first active regions AR1 of the double height cell DHC may be combined to serve as a single active region.

In an embodiment, the double height cell DHC shown in FIG. 2 may be defined as a multi-height cell. Although not shown, the multi-height cell may include a triple height cell whose cell height is about three times that of the single height cell SHC.

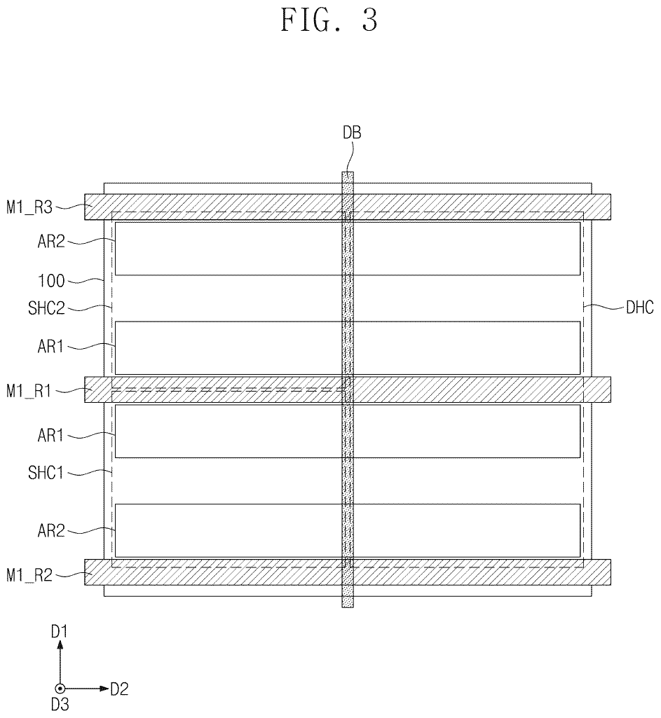

Referring to FIG. 3, a first single height cell SHC1, a second single height cell SHC2, and a double height cell DHC may be two-dimensionally disposed on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure DB.

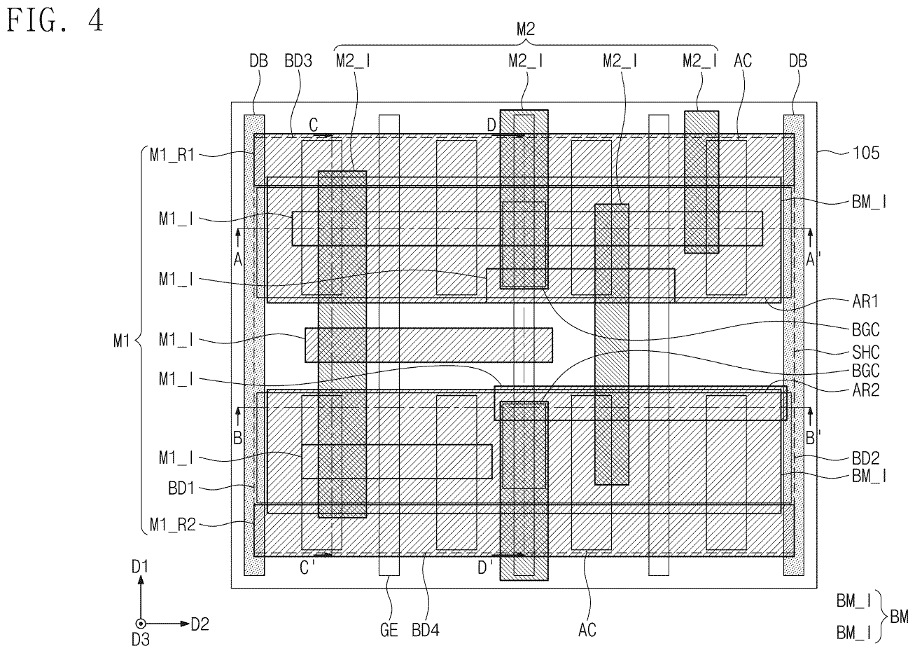

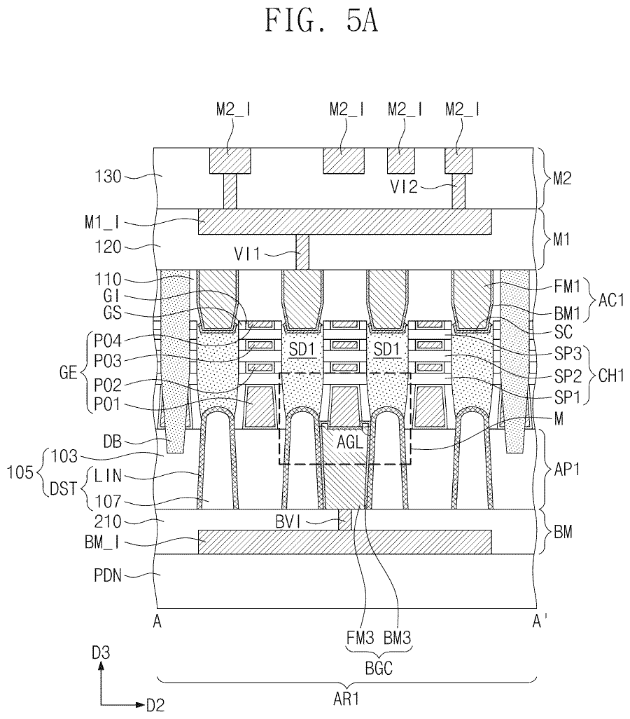

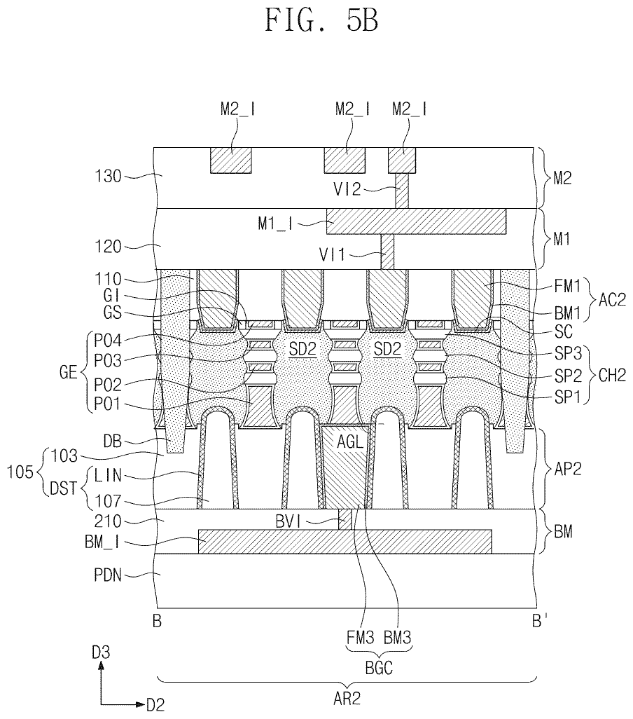

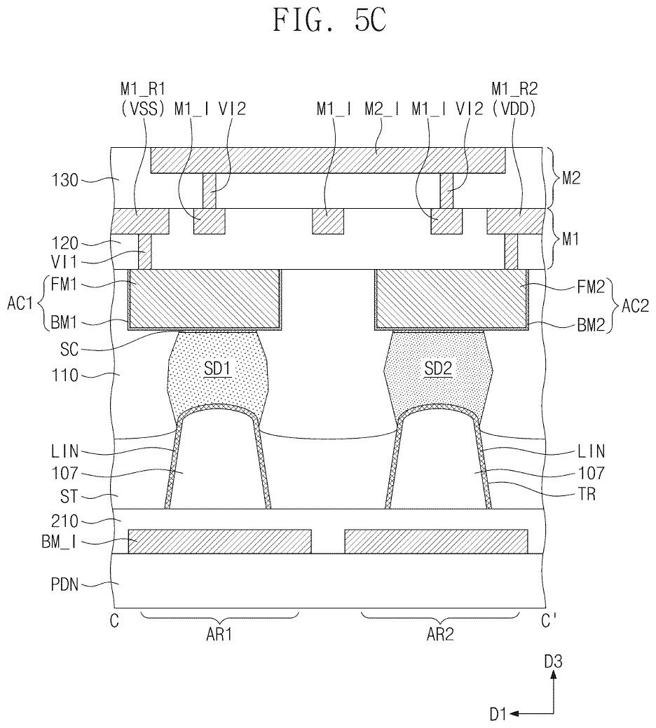

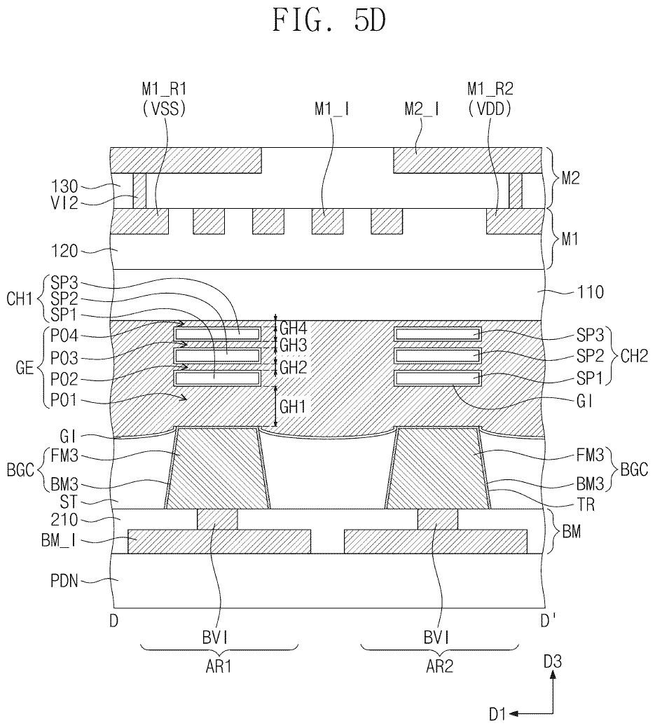

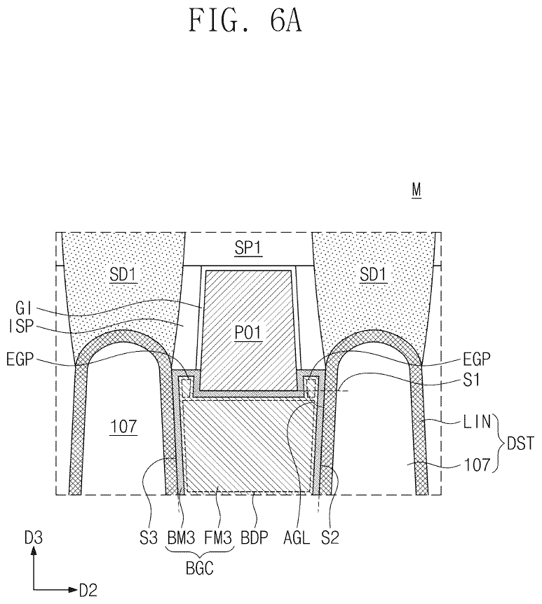

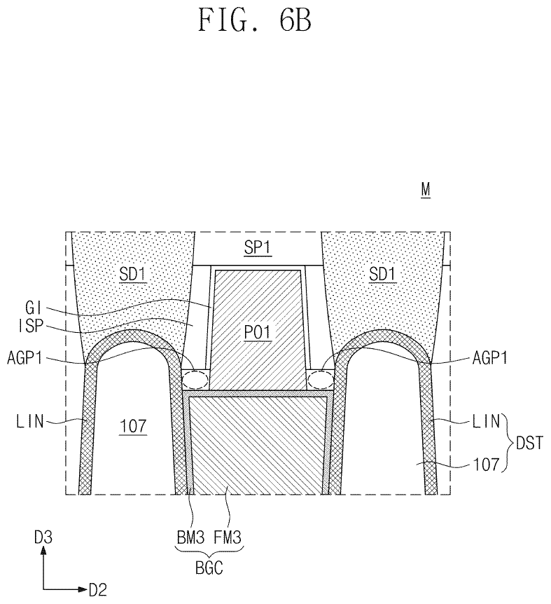

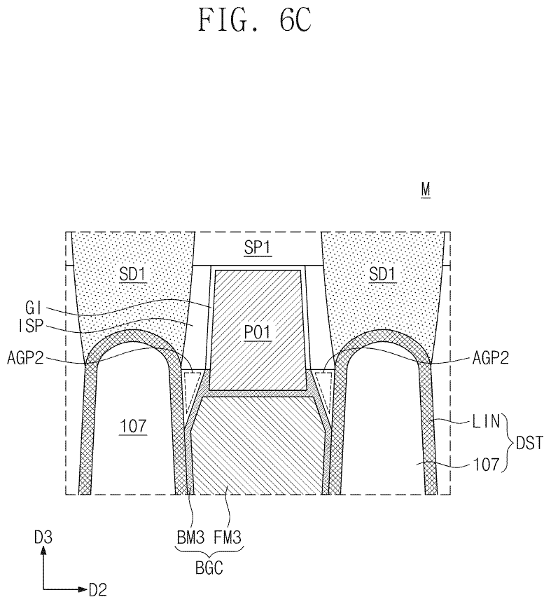

FIG. 4 is a plan view illustrating a semiconductor device according to an embodiment of inventive concepts. FIGS. 5A to 5D are sectional views taken along lines A-A′, B-B′, C-C′, and D-D′, respectively, of FIG. 4. FIG. 6A is an enlarged sectional view illustrating a portion ‘M’ of FIG. 5A, and FIGS. 6B and 6C are enlarged sectional views illustrating the portion ‘M’ of FIG. 5A according to some embodiments of inventive concepts. The semiconductor device of FIGS. 4 and 5A to 5D may be a concrete example of the single height cell SHC of FIG. 1.

Referring to FIGS. 4 and 5A to 5D, the single height cell SHC may be provided on a substrate 105. Logic transistors constituting a logic circuit may be disposed on the single height cell SHC. The substrate 105 may include a silicon-based insulating layer. In other words, the substrate 105 may be an insulating substrate. The substrate 105 may include a silicon oxide layer, a silicon nitride layer, or a silicon oxynitride layer. A back-side gate contact BGC, which will be described below, may be disposed in the substrate 105.

The substrate 105 may include the first and second active regions AR1 and AR2. Each of the first and second active regions AR1 and AR2 may be extended in the second direction D2. In an embodiment, the first active region ARI may be an NMOSFET region, and the second active region AR2 may be a PMOSFET region.

A first insulating pattern AP1 and a second insulating pattern AP2 may be defined by a trench TR formed in the substrate 105. The first insulating pattern AP1 may be provided on the first active region AR1, and the second insulating pattern AP2 may be provided on the second active region AR2. The first and second insulating patterns AP1 and AP2 may be extended in the second direction D2.

A device isolation layer ST may be provided on the trench TR formed in the substrate 105. That is, the device isolation layer ST may fill the trench TR. The device isolation layer ST may include a silicon oxide layer. The device isolation layer ST may not cover first and second channel patterns CH1 and CH2, which will be described below.

Referring back to FIGS. 5A and 5B, each of the first and second insulating patterns AP1 and AP2 may include a base pattern 103 and at least one insulating structure DST. The base pattern 103 may include a silicon nitride layer or a silicon oxynitride layer. In an embodiment, the base pattern 103 may be a silicon nitride layer. The insulating structure DST may be interposed between the base patterns 103. A width of the insulating structure DST in the second direction D2 may increase as it gets closer to a back-side metal layer BM to be described below. A top surface of the insulating structure DST may be in contact with each of first and second source/drain patterns SD1 and SD2, which will be described below. The insulating structure DST may have a convex shape toward each of the first and second source/drain patterns SD1 and SD2.

The insulating structure DST may include a basal dielectric pattern 107 and a liner layer LIN on the basal dielectric pattern 107. The uppermost surface of the basal dielectric pattern 107 may be located at a level higher than the uppermost surface of the base pattern 103. The basal dielectric pattern 107 may be formed of or include at least one of silicon oxide, silicon nitride, or silicon oxynitride. In an embodiment, the basal dielectric pattern 107 may be a silicon oxide layer.

The liner layer LIN may be provided to conformally cover the basal dielectric pattern 107. The liner layer LIN may cover the basal dielectric pattern 107 with a uniform thickness. In detail, the liner layer LIN may be continuously extended to cover side and top surfaces of the basal dielectric pattern 107. The liner layer LIN may be used to maintain the shape of the basal dielectric pattern 107 in a subsequent process of forming the back-side gate contact BGC and the back-side metal layer BM.

The liner layer LIN may include a material having an etch selectivity with respect to the base pattern 103. The liner layer LIN may include an oxide material. The liner layer LIN may include a silicon oxide layer or a titanium oxide layer. In an embodiment, the liner layer LIN may be formed of or include TiO₂.

A first channel pattern CH1 may be provided on the first insulating pattern AP1. A second channel pattern CH2 may be provided on the second insulating pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may be formed of or include at least one of silicon (Si), germanium (Ge), or silicon germanium (SiGe). For example, each of the first to third semiconductor patterns SP1, SP2, and SP3 may be formed of or include crystalline silicon (e.g., single crystalline silicon). In an embodiment, the first to third semiconductor patterns SP1, SP2, and SP3 may be a stack of nanosheets.

A plurality of first source/drain patterns SD1 may be provided on the first insulating pattern AP1. In detail, the first source/drain pattern SD1 may be provided on each of the insulating structures DST. A plurality of first recesses may be formed on the first insulating pattern AP1. The first source/drain patterns SD1 may be provided in the first recesses, respectively. The first source/drain patterns SD1 may be impurity regions of a first conductivity type (e.g., n-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the second insulating pattern AP2. In detail, the second source/drain pattern SD2 may be provided on each of the insulating structures DST. A plurality of second recesses may be formed on the second insulating pattern AP2. The second source/drain patterns SD2 may be provided in the second recesses, respectively. The second source/drain patterns SD2 may be impurity regions of a second conductivity type (e.g., p-type). The second channel pattern CH2 may be interposed between a pair of the second source/drain patterns SD2. In other words, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. In an embodiment, each of the first and second source/drain patterns SD1 and SD2 may have a top surface that is higher than a top surface of the third semiconductor pattern SP3. In another embodiment, a top surface of at least one of the first and second source/drain patterns SD1 and SD2 may be located at substantially the same level as the top surface of the third semiconductor pattern SP3.

In an embodiment, the first source/drain patterns SD1 may be formed of or include a semiconductor material (e.g., silicon (Si)). The second source/drain patterns SD2 may be formed of or include a semiconductor material (e.g., SiGe) whose lattice constant is larger than that of silicon (Si). In this case, the pair of the second source/drain patterns SD2 may exert a compressive stress on the second channel pattern CH2 therebetween.

Each of the second source/drain patterns SD2 may include a buffer layer and a main layer on the buffer layer. A volume of the main layer may be larger than a volume of the buffer layer. Each of the buffer and main layers may contain silicon germanium (SiGe). In detail, the buffer layer may contain germanium (Ge) of a relatively low concentration. In another embodiment, the buffer layer may be formed of or include only silicon (Si), without germanium (Ge). The germanium concentration of the buffer layer may range from 0 at % to 30 at %.

The main layer may contain germanium (Ge) of a relatively high concentration. In an embodiment, the germanium concentration of the main layer may range from 30 at % to 70 at %. The germanium concentration of the main layer may increase as a height in the third direction D3 increases. For example, the main layer adjacent to the buffer layer may have a germanium concentration of about 40 at %, and an upper portion of the main layer may have a germanium concentration of about 60 at %.

Each of the buffer and main layers may contain an impurity (e.g., boron, gallium, or indium) that allows the second source/drain pattern SD2 to have a p-type conductivity. The impurity concentration of each of the buffer and main layers may range from 1E18 atom/cm³ to 5E22 atom/cm³. The impurity concentration of the main layer may be higher than the impurity concentration of the buffer layer.

The buffer layer may protect the main layer during a process of replacing sacrificial layers SAL with first to third inner electrodes PO1, PO2, and PO3 of a gate electrode GE, which will be described below. For example, the buffer layer may limit and/or prevent an etchant material, which is used to remove the sacrificial layers SAL, from entering and etching the main layer. The first inner electrodes PO1 alternatively may be referred to as lower electrodes.

Each of the first source/drain patterns SD1 may be formed of or include silicon (Si). The first source/drain pattern SD1 may further include impurities (e.g., phosphorus, arsenic, or antimony) that allow the first source/drain pattern SD1 to have a n-type conductivity. The impurity concentration of the first source/drain pattern SD1 may range from 1E18 atom/cm³ to 5E22 atom/cm³.

In an embodiment, the second source/drain pattern SD2 may have an uneven or embossing side surface. In other words, the side surface of the second source/drain pattern SD2 may have a wavy profile. The side surface of the second source/drain pattern SD2 may protrude toward the first to third inner electrodes PO1, PO2, and PO3 of the gate electrode GE to be described below.

The gate electrodes GE may be provided on the first and second channel patterns CH1 and CH2. Each of the gate electrodes GE may be extended in the first direction D1 to cross the first and second channel patterns CH1 and CH2. Each of the gate electrodes GE may be vertically overlapped with the first and second channel patterns CH1 and CH2. The gate electrodes GE may be arranged at a first pitch in the second direction D2.

The gate electrode GE may include a first inner electrode PO1 interposed between each of the first and second insulating patterns AP1 and AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 5D, the gate electrode GE may be provided on a top surface, a bottom surface, and opposite side surfaces of each of the first to third semiconductor patterns SP1, SP2, and SP3. That is, the transistor according to the present embodiment may be a three-dimensional field effect transistor (e.g., MBCFET or GAAFET) in which the gate electrode GE is provided to three-dimensionally surround the channel pattern.

Each of the first to third inner electrodes PO1, PO2, and PO3 and the outer electrode PO4 of the gate electrode GE may have a height in the third direction D3. The third direction D3 may not be parallel to both the first and second directions D1 and D2. That is, the third direction D3 may be a direction that is perpendicular to the substrate 100.

The first inner electrode PO1 may have a first gate height GH1 (also referred to as first thickness GH1). The first gate height GH1 may be defined as a vertical distance from a top surface of the back-side gate contact BGC to a bottom surface of a gate insulating layer GI enclosing the first semiconductor pattern SP1.

The second inner electrode PO2 may have a second gate height GH2 (also referred to as second thickness GH2). The second gate height GH2 may be defined as a vertical distance from a top surface of the gate insulating layer GI enclosing the first semiconductor pattern SP1 to a bottom surface of the gate insulating layer GI enclosing the second semiconductor pattern SP2.

The third inner electrode PO3 may have a third gate height GH3 (also referred to as third thickness GH3). The third gate height GH3 may be defined as a vertical distance from a top surface of the gate insulating layer GI enclosing the second semiconductor pattern SP2 to a bottom surface of the gate insulating layer GI enclosing the third semiconductor pattern SP3.

The outer electrode PO4 may have a fourth gate height GH4 (also referred to fourth thickness GH4). The fourth gate height GH4 may be defined as a vertical distance from a top surface of the gate insulating layer GI enclosing the third semiconductor pattern SP3 to a bottom surface of a first interlayer insulating layer 110.

The first gate height GH1 may be larger than the fourth gate height GH4. The first gate height GH1 may be 1.5 to 4.0 times (or 2.5 to 3.5 times) the fourth gate height GH4. The fourth gate height GH4 may be equal to the second gate height GH2 and the third gate height GH3. In an embodiment, the first gate height GH1 may be substantially equal to the fourth gate height GH4.

For example, the first gate height GHI may range from 7.5 nm to 120 nm, and in particular, from 12.5 nm to 105 nm. Each of the second, third, and fourth gate heights GH2, GH3, and GH4 may range from 5.0 nm to 30.0 nm, and in particular, from 10.0 nm to 12.0 nm.

On the first active region AR1, inner spacers ISP may be respectively interposed between the first to third portions PO1, PO2, and PO3 of the gate electrode GE and the first source/drain pattern SD1. Each of the first to third inner electrodes PO1, PO2, and PO3 of the gate electrode GE may be spaced apart from the first source/drain pattern SD1, with the inner spacer ISP interposed therebetween. The inner spacer ISP may limit and/or prevent a leakage current from the gate electrode GE.

Referring back to FIGS. 4 and 5A to 5D, a pair of gate spacers GS may be respectively disposed on opposite side surfaces of the outer electrode PO4 of the gate electrode GE. The gate spacers GS may be extended along the gate electrode GE and in the first direction D1. Top surfaces of the gate spacers GS may be coplanar with a top surface of the outer electrode PO4 of the gate electrode GE. In an embodiment, the gate spacers GS may be formed of or include at least one of SiCN, SiCON, or SiN. In another embodiment, the gate spacers GS may be a multi-layered structure, which is formed of or includes at least two different materials selected from SiCN, SiCON, and SiN.

In an embodiment, although not shown, a gate capping pattern may be provided on the gate electrode GE. The gate capping pattern may be extended along the gate electrode GE and in the first direction D1. The gate capping pattern may be formed of or include a material having an etch selectivity with respect to the first and second interlayer insulating layers 110 and 120. In detail, the gate capping pattern may be formed of or include at least one of SiON, SiCN, SiCON, or SiN.

The gate insulating layer GI may be interposed between the gate electrode GE and the first channel pattern CH1 and between the gate electrode GE and the second channel pattern CH2. The gate insulating layer GI may cover top, bottom, and opposite side surfaces of each of the first to third semiconductor patterns SP1, SP2, and SP3. The gate insulating layer GI may cover the top surface of the device isolation layer ST below the gate electrode GE.

In an embodiment, the gate insulating layer GI may include a silicon oxide layer, a silicon oxynitride layer, and/or a high-k dielectric layer. For example, the gate insulating layer GI may have a structure, in which a silicon oxide layer and a high-k dielectric layer are stacked. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In another embodiment, the semiconductor device may include a negative capacitance (NC) FET using a negative capacitor. For example, the gate insulating layer GI may include a ferroelectric layer exhibiting a ferroelectric property and a paraelectric layer exhibiting a paraelectric property.

The ferroelectric layer may have a negative capacitance, and the paraelectric layer may have a positive capacitance. In the case where two or more capacitors are connected in series and each capacitor has a positive capacitance, a total capacitance may be reduced to a value that is less than a capacitance of each of the capacitors. By contrast, in the case where at least one of serially-connected capacitors has a negative capacitance, a total capacitance of the serially-connected capacitors may have a positive value and may be greater than an absolute value of each capacitance.

In the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS), which is less than 60 mV/decade, at the room temperature.

The ferroelectric layer may have the ferroelectric property. The ferroelectric layer may be formed of or include at least one of, for example, hafnium oxide, hafnium zirconium oxide, barium strontium titanium oxide, barium titanium oxide, and/or lead zirconium titanium oxide. Here, the hafnium zirconium oxide may be hafnium oxide that is doped with zirconium (Zr). Alternatively, the hafnium zirconium oxide may be a compound composed of hafnium (Hf), zirconium (Zr), and/or oxygen (O).

The ferroelectric layer may further include dopants. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The kind of the dopants in the ferroelectric layer may vary depending on a ferroelectric material included in the ferroelectric layer.

In the case where the ferroelectric layer includes hafnium oxide, the dopants in the ferroelectric layer may include at least one of, for example, gadolinium (Gd), silicon (Si), zirconium (Zr), aluminum (Al), and/or yttrium (Y).

In the case where the dopants are aluminum (Al), a content of aluminum in the ferroelectric layer may range from 3 to 8 at % (atomic percentage). Here, the content of the dopants (e.g., aluminum atoms) may be a ratio of the number of aluminum atoms to the number of hafnium and aluminum atoms.

In the case where the dopants are silicon (Si), a content of silicon in the ferroelectric layer may range from 2 at % to 10 at %. In the case where the dopants are yttrium (Y), a content of yttrium in the ferroelectric layer may range from 2 at % to 10 at %. In the case where the dopants are gadolinium (Gd), a content of gadolinium in the ferroelectric layer may range from 1 at % to 7 at %. In the case where the dopants are zirconium (Zr), a content of zirconium in the ferroelectric layer may range from 50 at % to 80 at %.

The paraelectric layer may have the paraelectric property. The paraelectric layer may be formed of or include at least one of, for example, silicon oxide and/or high-k metal oxides. The metal oxides, which can be used as the paraelectric layer, may include at least one of, for example, hafnium oxide, zirconium oxide, and/or aluminum oxide, but inventive concepts are not limited to these examples.

The ferroelectric layer and the paraelectric layer may be formed of or include the same material. The ferroelectric layer may have the ferroelectric property, but the paraelectric layer may not have the ferroelectric property. For example, in the case where the ferroelectric and paraelectric layers contain hafnium oxide, a crystal structure of the hafnium oxide in the ferroelectric layer may be different from a crystal structure of the hafnium oxide in the paraelectric layer.

The ferroelectric layer may exhibit the ferroelectric property, only when its thickness is in a specific range. In an embodiment, the ferroelectric layer may have a thickness ranging from 0.5 to 10 nm, but inventive concepts are not limited to this example. Since a critical thickness associated with the occurrence of the ferroelectric property varies depending on the kind of the ferroelectric material, the thickness of the ferroelectric layer may be changed depending on the kind of the ferroelectric material.

As an example, the gate insulating layer GI may include a single ferroelectric layer. As another example, the gate insulating layer GI may include a plurality of ferroelectric layers spaced apart from each other. The gate insulating layer GI may have a multi-layered structure, in which a plurality of ferroelectric layers and a plurality of paraelectric layers are alternately stacked.

Referring back to FIGS. 4 and 5A to 5D, the gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third inner electrodes PO1, PO2, and PO3 of the gate electrode GE may be composed of the first metal pattern or the work-function metal.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers, which are stacked.

The second metal pattern may be formed of or include a metallic material whose resistance is lower than the first metal pattern. For example, the second metal pattern may include at least one metallic material, which is selected from the group consisting of tungsten (W), aluminum (Al), titanium (Ti), and tantalum (Ta). The outer electrode PO4 of the gate electrode GE may include the first metal pattern and the second metal pattern on the first metal pattern.

The first interlayer insulating layer 110 may be provided on the substrate 105. The first interlayer insulating layer 110 may cover the gate spacers GS, the outer electrode PO4 of the gate electrode GE, and the first and second source/drain patterns SD1 and SD2. A top surface of the first interlayer insulating layer 110 may be substantially coplanar with top surfaces of a first active contact AC1 and a second active contact AC2, which will be described below. A second interlayer insulating layer 120 may be provided on the first interlayer insulating layer 110. A third interlayer insulating layer 130 may be provided on the second interlayer insulating layer 120. In an embodiment, each of the first to third interlayer insulating layers 110, 120, and 130 may include a silicon oxide layer.

The single height cell SHC may have a first border BD1 and a second border BD2, which are opposite to each other in the second direction D2. The first and second borders BD1 and BD2 may be extended in the first direction D1. The single height cell SHC may have a third border BD3 and a fourth border BD4, which are opposite to each other in the first direction D1. The third and fourth borders BD3 and BD4 may be extended in the second direction D2.

A pair of division structures DB, which are opposite to each other in the second direction D2, may be provided at both sides of the single height cell SHC. For example, the pair of the division structures DB may be respectively provided on the first and second borders BD1 and BD2 of the single height cell SHC. The division structure DB may be extended in the first direction D1 to be parallel to the gate electrodes GE. A pitch between the division structure DB and the gate electrode GE adjacent thereto may be equal to the first pitch.

The division structure DB may be provided to penetrate the first interlayer insulating layer 110 and may be extended into the first and second insulating patterns AP1 and AP2. The division structure DB may be provided to penetrate an upper portion of each of the first and second insulating patterns AP1 and AP2. The division structure DB may electrically separate an active region of the single height cell SHC from an active region of a neighboring cell.

The first and second active contacts AC1 and AC2 may be provided to penetrate the first interlayer insulating layer 110 and may be electrically connected to the first and second source/drain patterns SD1 and SD2, respectively. A pair of active contacts AC1 and AC2 may be respectively provided at both sides of the gate electrode GE. When viewed in a plan view, each of the first and second active contacts AC1 and AC2 may have a bar-shaped pattern that is extended in the first direction D1.

Each of the first and second active contacts AC1 and AC2 may be a self-aligned contact plug. In other words, the first and second active contacts AC1 and AC2 may be formed by a self-alignment process using the gate spacer GS.

Metal-semiconductor compound layers SC (e.g., silicide layers) may be respectively interposed between the first active contact AC1 and the first source/drain pattern SD1 and between the second active contact AC2 and the second source/drain pattern SD2. The metal-semiconductor compound layer SC may lower a contact resistance between the first active contact AC1 and the first source/drain pattern SD1 and a contact resistance between the second active contact AC2 and the second source/drain pattern SD2. The first and second active contacts AC1 and AC2 may be electrically connected to the source/drain patterns SD1 and SD2 through the metal-semiconductor compound layer SC. For example, the metal-semiconductor compound layer SC may be formed of or include at least one of titanium silicide, tantalum silicide, tungsten silicide, nickel silicide, or cobalt silicide.

The first active contact AC1 may include a first conductive pattern FM1 and a first barrier pattern BM1 enclosing the first conductive pattern FM1, and the second active contact AC2 may include a second conductive pattern FM2 and a second barrier pattern BM2 enclosing the second conductive pattern FM2. For example, each of the conductive patterns FM1 and FM2 may be formed of or include at least one of metallic materials (e.g., aluminum, copper, tungsten, molybdenum, and cobalt). Each of the barrier patterns BM1 and BM2 may cover side and bottom surfaces of each of the conductive patterns FM1 and FM2. Each of the barrier patterns BM1 and BM2 may include a metal layer or a metal nitride layer. The metal layer may be formed of or include at least one of titanium, tantalum, tungsten, nickel, cobalt, and platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

A first metal layer M1 may be provided in the second interlayer insulating layer 120. For example, the first metal layer M1 may include the first power line M1_R1, the second power line M1_R2, and first interconnection lines M1_I. The interconnection lines M1_R1, M1_R2, and M1_I of the first metal layer M1 may be extended in the second direction D2 to be parallel to each other.

In detail, the first and second power lines M1_R1 and M1_R2 may be respectively provided on the third and fourth borders BD3 and BD4 of the single height cell SHC. The first power line M1_R1 may be extended along the third border BD3 and in the second direction D2. The second power line M1_R2 may be extended along the fourth border BD4 and in the second direction D2.

The first interconnection lines M1_I of the first metal layer M1 may be disposed between the first and second power lines M1_R1 and M1_R2. The first interconnection lines M1_I of the first metal layer M1 may be arranged at a second pitch in the first direction D1. The second pitch may be smaller than the first pitch. A linewidth of each of the first interconnection lines M1_I may be smaller than a linewidth of each of the first and second power lines M1_R1 and M1_R2.

The first metal layer M1 may further include first vias VI1. The first vias VI1 may be provided below the interconnection lines M1_R1, M1_R2, and M1_I, respectively, of the first metal layer M1. The first and second active contacts AC1 and AC2 may be electrically connected to the interconnection line of the first metal layer M1 through the first via VI1.

The interconnection line of the first metal layer M1 and the first via VII thereunder may be formed by separate processes. For example, the interconnection line and the first via VI1 of the first metal layer M1 may be independently formed by respective single damascene processes. The semiconductor device according to the present embodiment may be fabricated using a sub-20 nm process.

A second metal layer M2 may be provided in the third interlayer insulating layer 130. The second metal layer M2 may include a plurality of second interconnection lines M2_I. Each of the second interconnection lines M2_I of the second metal layer M2 may be a line-or bar-shaped pattern that is extended in the first direction D1. In other words, the second interconnection lines M2_I may be extended in the first direction D1 to be parallel to each other.

The second metal layer M2 may further include second vias VI2, which are respectively provided below the second interconnection lines M2_I. The interconnection lines of the first and second metal layers M1 and M2 may be electrically connected to each other through the second via VI2. The interconnection line of the second metal layer M2 and the second via VI2 thereunder may be formed together by a dual damascene process.

The interconnection lines of the first metal layer M1 may be formed of or include a conductive material that is the same as or different from those of the second metal layer M2. For example, the interconnection lines of the first and second metal layers M1 and M2 may be formed of or include at least one of metallic materials (e.g., aluminum, copper, tungsten, ruthenium, molybdenum, and cobalt). Although not shown, a plurality of metal layers (e.g., M3, M4, M5, and so forth) may be additionally stacked on a fourth interlayer insulating layer. Each of the stacked metal layers may include interconnection lines, which are used as routing paths between cells.

Referring back to FIGS. 4, 5A, 5B, 5D, and 6A, the back-side gate contact BGC may be provided between a pair of the insulating structures DST. In detail, the back-side gate contact BGC may be provided to penetrate the base pattern 103 of each of the first and second insulating patterns AP1 and AP2 and may be electrically connected to the gate electrode GE. When viewed in a plan view, the back-side gate contact BGC may be a bar-shaped pattern which is extended in the first direction D1.

The back-side gate contact BGC may be a self-aligned contact, which is extended from a backside surface of the substrate 105. For example, the back-side gate contact BGC may be formed by a self-alignment process using the insulating structures DST.

The top surface of the back-side gate contact BGC may be in contact with a bottom surface of the first inner electrode PO1 of the gate electrode GE. The back-side gate contact BGC may be interposed between the insulating structures DST and may have a side surface that is in contact with a side surface of the insulating structures DST. An angle AGL between the top surface of the back-side gate contact BGC and the side surface of the back-side gate contact BGC may be an acute angle (e.g., ranging from 45° to90°).

The back-side gate contact BGC may include a third conductive pattern FM3 and a third barrier pattern BM3 enclosing the third conductive pattern FM3. The third conductive pattern FM3 may be formed of or include the same material as the first and second conductive patterns FM1 and FM2, and the third barrier pattern BM3 may be formed of or include the same material as the first and second barrier patterns BM1 and BM2. The third conductive pattern FM3 may be formed of or include at least one of metallic materials (e.g., aluminum, copper, tungsten, molybdenum, and cobalt). For example, the third barrier pattern BM3 may include a metal layer or a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

The third barrier pattern BM3 may cover side and top surfaces of the third conductive pattern FM3. For example, the third barrier pattern BM3 may be continuously extended to cover the side and top surfaces of the third conductive pattern FM3.

Referring to FIGS. 5A and 6A, a width of the back-side gate contact BGC in the second direction D2 may decrease as it gets closer to the back-side metal layer BM. The back-side gate contact BGC may have a first surface S1, which corresponds to a top surface thereof, and a second surface S2 and a third surface S3, which respectively correspond to side surfaces thereof. The first surface S1 may be in contact with the bottom surface of the first inner electrode PO1. The second surface S2 may be in contact with a side surface of the insulating structure DST. The second and third surfaces S2 and S3 may be opposite to each other in the second direction D2.

The second surface S2 may have a positive slope, and the third surface S3 may have a negative slope. An angle AGL between the first and second surfaces S1 and S2 may be an acute angle (e.g., ranging from 45° to 90°). An angle between the first and third surfaces S1 and S3 may be an acute angle.

The back-side gate contact BGC may include the third conductive pattern FM3 and the third barrier pattern BM3 on the third conductive pattern FM3. The third conductive pattern FM3 may include a body portion BDP and an edge portion EGP. The body portion BDP may be interposed between a pair of the insulating structures DST and may be spaced apart from the liner layer LIN, with the third barrier pattern BM3 interposed therebetween. The edge portions EGP may be provided at both sides of the body portion BDP. The edge portion EGP may have a shape protruding from the body portion BDP toward the inner spacer ISP. A top surface of the edge portion EGP may be located at a level higher than a top surface of the body portion BDP.

The third barrier pattern BM3 may be continuously extended to cover side and top surfaces of the body and edge portions BDP and EGP. Furthermore, the third barrier pattern BM3 on the edge portion EGP may be in contact with a bottom surface of each of the inner spacer ISP and the gate insulating layer GI.

In the semiconductor device according to an embodiment of inventive concepts, since the back-side gate contact BGC is connected to the gate electrode GE through the backside surface of the substrate 105, it may be possible to simplify a back-end-of-line (BEOL) process of forming a metal line on a frontside surface of the substrate 105. In other words, it may be possible to reduce the difficulty in a metal patterning process of forming an interconnection pattern.

In the semiconductor device according to an embodiment of inventive concepts, by lowering a pattern density (i.e., a metal route density) of the first and second metal layers M1 and M2 provided on the frontside surface of the substrate 105, it may be possible to increase a signal transferring speed in a process of transmitting an electrical signal to a transistor. In addition, it may be possible to limit and/or prevent a short circuit issue between the contacts and the interconnection line, which are formed in a middle-end-of-line (MOL) process. That is, it may be possible to improve the electrical and reliability characteristics of the semiconductor device.

In sum, by forming the back-side gate contact BGC in the afore-mentioned manner, it may be possible to improve the electrical and reliability characteristics of the semiconductor device and the efficiency in the fabrication process thereof.

Referring back to FIGS. 4 and 5A to 5D, the back-side metal layer BM may be provided below the substrate 105. For example, the back-side metal layer BM may include backside interconnection lines BM_I. The backside interconnection lines BM_I of the back-side metal layer BM may be extended in the second direction D2 to be parallel to each other. In an embodiment, the backside interconnection lines BM_I may be vertically overlapped with each of the first and second active regions AR1 and AR2.

The back-side metal layer BM may further include backside vias BVI. The backside vias BVI may be provided between the backside interconnection line BM_I and the back-side gate contact BGC. That is, the back-side gate contact BGC and the backside interconnection line BM_I may be electrically connected to each other through the backside via BVI.

The backside interconnection line BM_I of the back-side metal layer BM and the backside via BVI thereon may be separately formed by different processes. For example, each of the backside interconnection line BM_I and the backside via BVI may be formed by a single damascene process. The semiconductor device according to the present embodiment may be fabricated using a sub-20 nm process. The backside interconnection line BM_I and the backside via BVI may be formed of or include at least one selected from the group consisting of copper, molybdenum, tungsten, and ruthenium.

A power delivery network layer PDN may be provided on a bottom surface of the back-side metal layer BM. The power delivery network layer PDN may include a plurality of lower interconnection lines, which are electrically connected to the backside interconnection lines BM_I. In an embodiment, the power delivery network layer PDN may include an interconnection network, which is used to apply a gate voltage (Gate on/off) to the backside interconnection lines BM_I.

In the following description, an element previously described with reference to FIGS. 4, 5A to 5D, and 6A may be identified by the same reference number without repeating an overlapping description thereof, for concise description. FIGS. 6B and 6C are enlarged sectional views illustrating the portion ‘M’ of FIG. 5A according to some embodiments of inventive concepts.

Referring to FIG. 6B, a first air gap pattern AGP1 may be interposed between the back-side gate contact BGC and the inner spacer ISP. The first air gap pattern AGP1 may be surrounded by the insulating structure DST, the inner spacer ISP, the gate insulating layer GI, the first inner electrode PO1, and the back-side gate contact BGC. The first air gap pattern AGP1 may be an empty space, which is formed depending on an aspect ratio and a step coverage property of the back-side gate contact BGC. For example, the first air gap pattern AGP1 may be a void. The first gap pattern AGP1 may include an insulating material defining the void and surrounded by the insulating structure DST, the inner spacer ISP, the gate insulating layer GI, the first inner electrode PO1, and the back-side gate contact BGC.

The first air gap pattern AGP1 may have various shapes, which are allowed for the void. For example, the first air gap pattern AGP1 may have a circular, elliptical, or cylindrical shape, when viewed in a plan view. The first air gap pattern AGP1 may have a tetragonal, pentagonal, or polygonal shape, when viewed in a section taken along the line A-A′ of FIG. 4.

The inner spacer ISP and the back-side gate contact BGC may be spaced apart from each other with the first air gap pattern AGP1 interposed therebetween, and a portion of the third barrier pattern BM3 of the back-side gate contact BGC may be in contact with the bottom surface of the first inner electrode PO1. A bottom surface of the inner spacer ISP may be located at a level higher than the bottom surface of the first inner electrode PO1. Similarly, a bottom surface of the gate insulating layer GI may be located at a level higher than the bottom surface of the first inner electrode PO1.

Referring to FIG. 6C, a second air gap pattern AGP2 may be interposed between the back-side gate contact BGC and the inner spacer ISP. The second air gap pattern AGP2 may be surrounded by the insulating structure DST, the inner spacer ISP, and the back-side gate contact BGC. The second air gap pattern AGP2 may be an empty space, which is formed depending on an aspect ratio and a step coverage property of the back-side gate contact BGC. For example, the second air gap pattern AGP2 may be a void. The second gap pattern AGP2 may include an insulating material defining the void and surrounded by the insulating structure DST, the inner spacer ISP, the gate insulating layer GI, the first inner electrode PO1, and the back-side gate contact BGC.

The second air gap pattern AGP2 may have various shapes, which are allowed for the void. For example, the second air gap pattern AGP2 may be a void that is shaped like a seam or a slit. A width of the second air gap pattern AGP2 in the second direction D2 may decrease in a downward direction (e.g., as a height in the third direction D3 decreases).

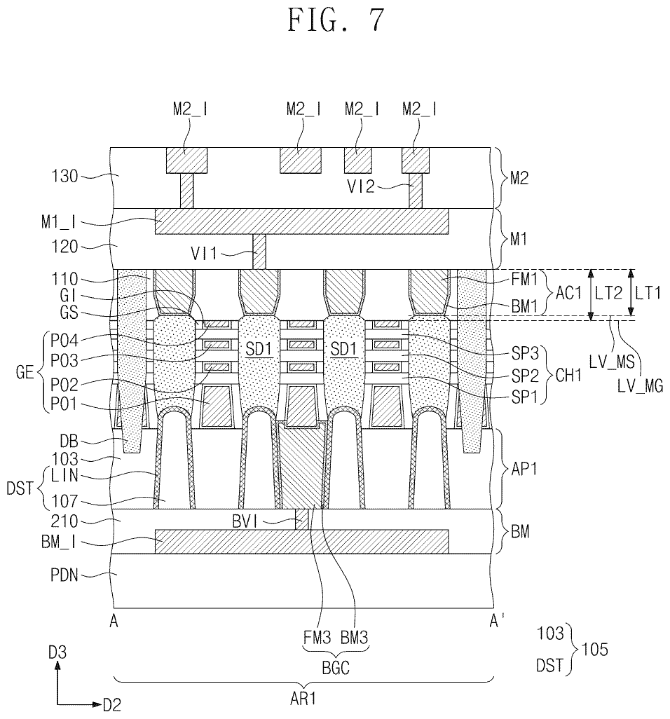

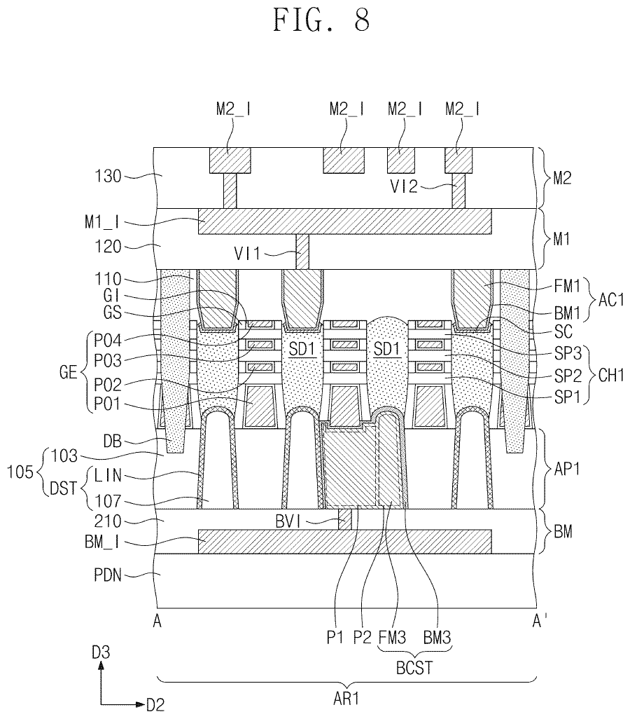

In the following description, an element previously described with reference to FIGS. 4 and 5A to 5D may be identified by the same reference number without repeating an overlapping description thereof, for concise description. FIGS. 7 and 8 are sectional views illustrating other examples of FIG. 5A.

Referring to FIG. 7, the first source/drain pattern SD1 may be formed by over-growing an epitaxial pattern using a selective epitaxial growth (SEG) process. As a height of the first source/drain pattern SD1 in the third direction D3 increases, a height of the first active contact AC1 in the third direction D3 may decreases.

A level of a top surface of the first source/drain pattern SD1 in the third direction D3 may be defined as a first level LV_MS. For example, at the first level LV_MS, the top surface of the first source/drain pattern SD1 may be in contact with a bottom surface of the first active contact AC1. A level of a top surface of the outer electrode PO4 in the third direction D3 may be defined as a second level LV_MG. At the second level LV_MG, the top surface of the outer electrode PO4 may be in contact with a bottom surface of the first interlayer insulating layer 110.

The top surface of the first interlayer insulating layer 110 may be substantially coplanar with top surfaces of the first active contact AC1 and the division structure DB. A vertical distance from the top surface of the first interlayer insulating layer 110 to the top surface of the first source/drain pattern SD1 may be defined as a first length LT1. A vertical distance from the top surface of the first interlayer insulating layer 110 to the top surface of the outer electrode PO4 may be defined as a second length LT2.

The first level LV_MS may be higher than the second level LV_MG in the third direction D3. That is, the uppermost surface of the first source/drain pattern SD1 may be higher than the uppermost surface of the outer electrode PO4. Since a level of the uppermost surface of the outer electrode PO4 is lower than a level of the first source/drain pattern SD1, the first length LT1 may be smaller than the second length LT2. In an embodiment, the first level LV_MS and the second level LV_MG may be located at the same level, and the first length LT1 and the second length LT2 may be equal to each other.

In the semiconductor device according to an embodiment of inventive concepts, by overgrowing the first source/drain pattern SD1 and reducing the height of the first active contact AC1, a middle end-of-line (MOL) process of connecting the transistor to the metal line may be more easily performed. For example, it may be possible to omit a deep etching process, which is required when the first active contact AC1 is formed to have a large height, and thereby to reduce technical difficulties in a process of forming the first active contact AC1.

In the case where the first active contact AC1 is formed in the afore-mentioned manner, it may be possible to minimize loss of the first source/drain pattern SD1 and thereby to improve the reliability of the semiconductor device.

In sum, by forming the first active contact AC1 in the afore-mentioned manner, it may be possible to improve the reliability of the semiconductor device and the efficiency of the fabrication process.

Referring to FIG. 8, a backside conductive structure BCST may be provided between the insulating structure DST and the base pattern 103. In detail, the backside conductive structure BCST may be provided to penetrate the first insulating pattern AP1 and electrically connect the gate electrode GE to the first source/drain pattern SD1. When viewed in a plan view, the backside conductive structure BCST may be a bar-shaped pattern which is extended in the first direction D1. A width of the backside conductive structure BCST in the second direction D2 may be larger than a width of the back-side gate contact BGC of FIG. 5A in the second direction D2.

The backside conductive structure BCST may be a self-aligned contact, which is extended from the backside surface of the substrate 105. For example, the backside conductive structure BCST may be formed by a self-aligned method using the insulating structure DST and the base pattern 103.

A top surface of the backside conductive structure BCST may be in contact with the bottom surface of the first inner electrode PO1 of the gate electrode GE and the bottom surface of the first source/drain pattern SD1. A side surface of the backside conductive structure BCST may be in contact with a side surface of the insulating structure DST, and an opposite side surface of the backside conductive structure BCST may be in contact with a side surface of the base pattern 103.

The backside conductive structure BCST may include the third conductive pattern FM3 and the third barrier pattern BM3 enclosing the third conductive pattern FM3. The third conductive pattern FM3 may include the same material as the first and second conductive patterns FM1 and FM2, and the third barrier pattern BM3 may include the same material as the first and second barrier patterns BM1 and BM2. For example, the third conductive pattern FM3 may be formed of or include at least one of metallic materials (e.g., aluminum, copper, tungsten, molybdenum, and cobalt). For example, the third barrier pattern BM3 may include a metal layer or a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

The third barrier pattern BM3 may cover side and top surfaces of the third conductive pattern FM3. For example, the third barrier pattern BM3 may be continuously extended to cover the side and top surfaces of the third conductive pattern FM3.

The backside conductive structure BCST may include a first portion P1 provided below the gate electrode GE and a second portion P2 provided below the first source/drain pattern SD1. A top surface of the first portion PI may be in contact with the bottom surface of the first inner electrode PO1, the bottom surface of the gate insulating layer GI, and the bottom surface of the inner spacer ISP. The first portion PI may include sub-portions, which correspond to the body and edge portions BDP and EGP described with reference to FIG. 6A.

A top surface of the second portion P2 may be in contact with a bottom surface of the first source/drain pattern SD1. The second portion P2 may be convex toward the first source/drain pattern SD1. The uppermost surface of the second portion P2 may be located at a level higher than the uppermost surface of the first portion P1 in the third direction D3.

An angle between the top surface of the first portion P1 of the backside conductive structure BCST and a side surface of the backside conductive structure BCST, which is in contact with the insulating structure DST, may be an acute angle (e.g., 45° to 90°).

Although not shown, a void may be provided between the first portion P1 and the inner spacer ISP. The void may have a circular, elliptical, or cylindrical shape.

The first portion P1 may be vertically overlapped with the gate electrode GE and the backside via BVI. The second portion P2 may be vertically overlapped with the first source/drain pattern SD1. The first active contact AC1 may not be formed on the first source/drain pattern SD1, which is placed on the second portion P2.

In the semiconductor device according to an embodiment of inventive concepts, the backside conductive structure BCST may be formed as a single object that is in contact with the gate electrode GE and the first source/drain pattern SD1, and this may make it possible to simplify a back-end-of-line (BEOL) process of forming a metal line on the frontside surface of the substrate 105. In addition, a metal patterning process of forming an interconnection pattern may be performed with reduced technical difficulty. Owing to the backside conductive structure BCST, it may be possible to improve the efficiency in a process of fabricating a semiconductor device.

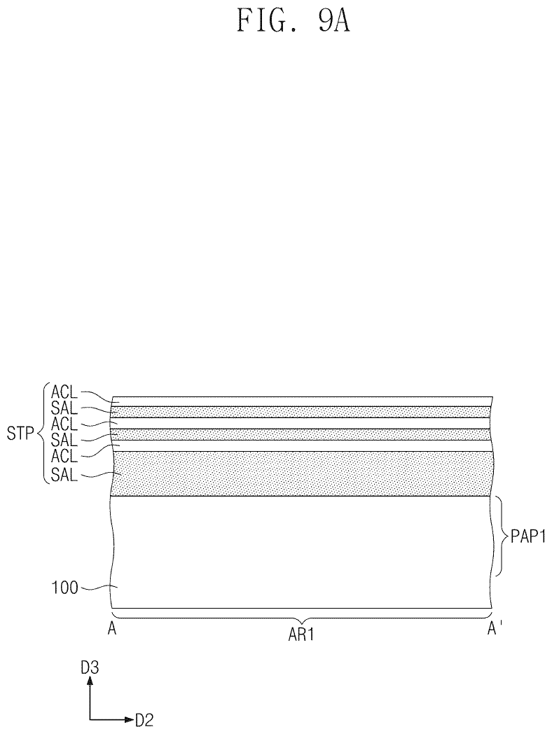

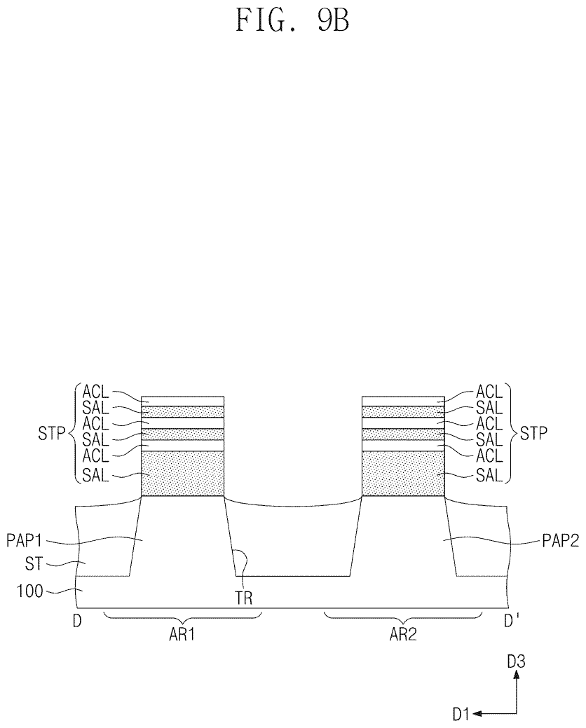

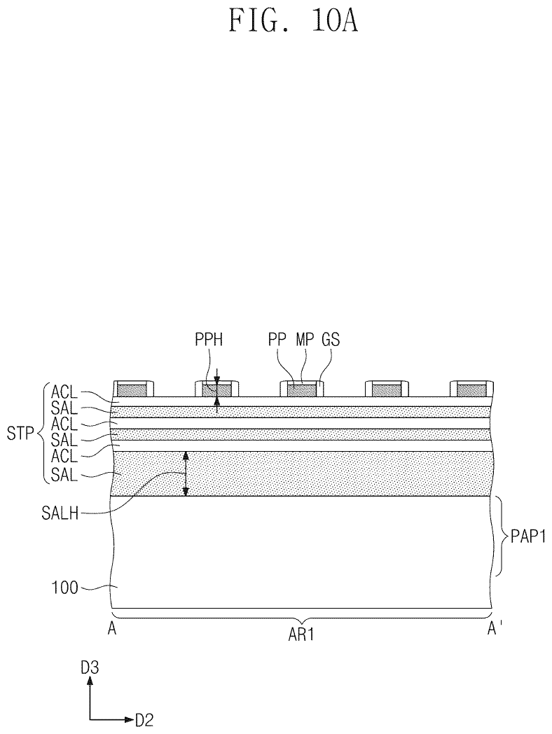

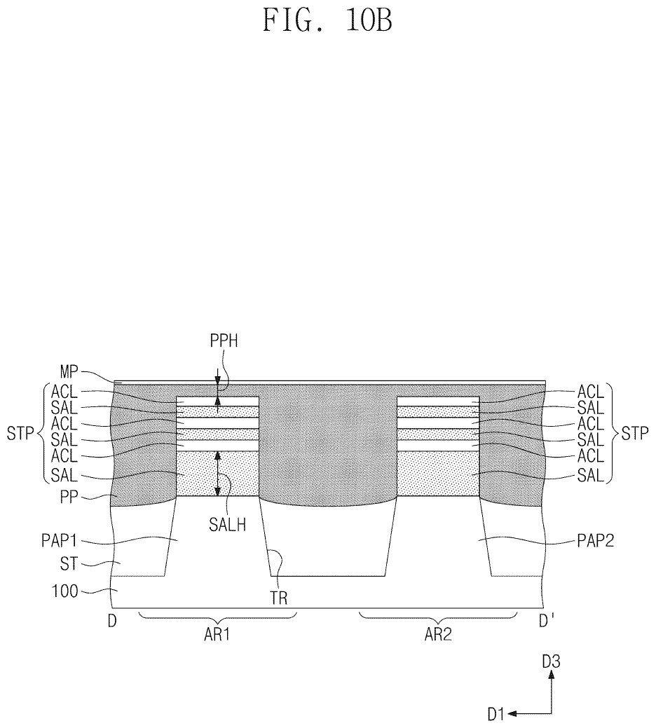

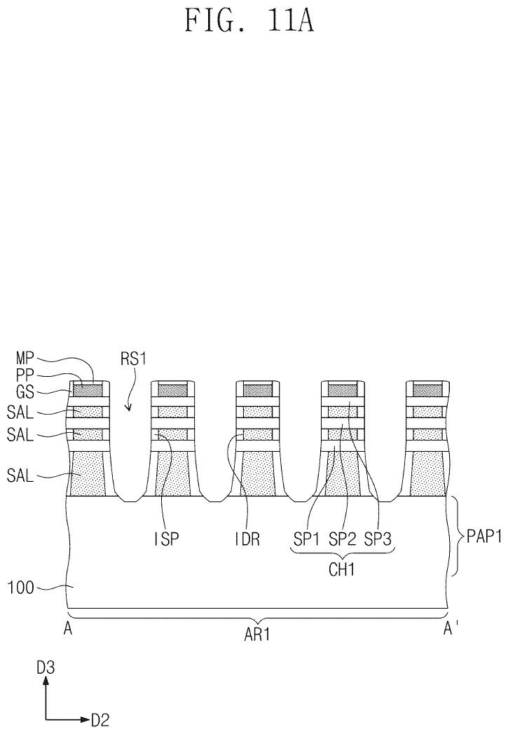

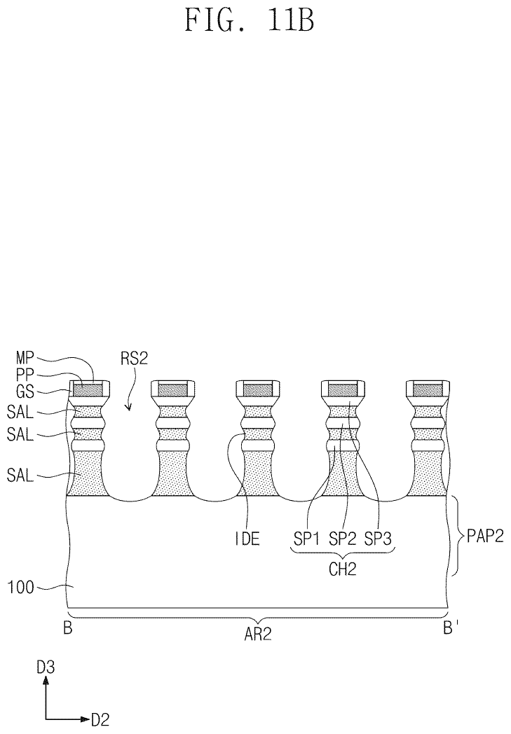

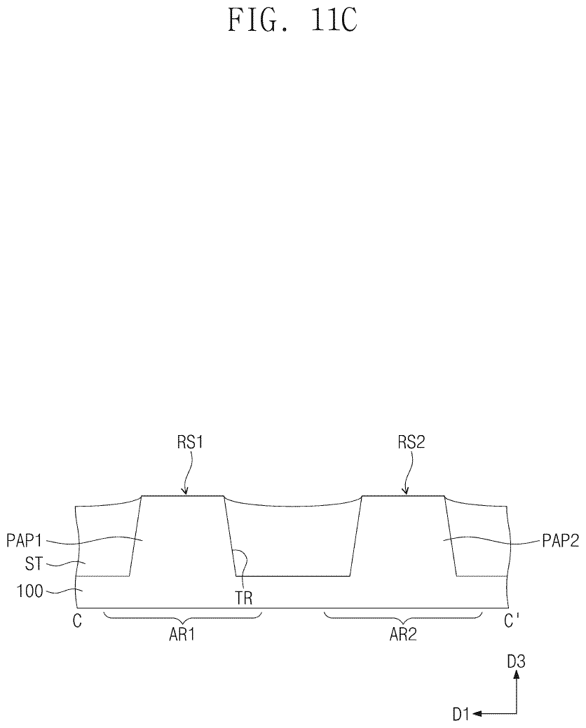

FIGS. 9A to 20D are sectional views illustrating a method of fabricating a semiconductor device according to an embodiment of inventive concepts. In detail, FIGS. 9A, 10A, 11A, 12A, 13A, 14A, 15A, 16A, 17A, 18A, 19A, and 20A are sectional views corresponding to a line A-A′ of FIG. 4. FIGS. 11B, 12B, 13B, 14B, 15B, 16B, 17B, 18B, 19B, and 20B are sectional views corresponding to a line B-B′ of FIG. 4. FIGS. 11C, 12C, 13C, 14C, 15C, 16C, 17C, 18C, 19C, and 20C are sectional views corresponding to a line C-C′ of FIG. 4. FIGS. 9B, 10B, 13D, 14D, 15D, 16D, 17D, 18D, 19D, and 20D are sectional views corresponding to a line D-D′ of FIG. 4.

Referring to FIGS. 9A and 9B, the substrate 100 including the first and second active regions AR1 and AR2 may be provided. The substrate 100 may be a semiconductor substrate that is formed of or includes silicon, germanium, silicon germanium, a compound semiconductor material, or the like. In an embodiment, the substrate 100 may be a silicon substrate. Active and sacrificial layers ACL and SAL may be alternately stacked on the substrate 100. The active and sacrificial layers ACL and SAL may be formed of or include at least one of silicon (Si), germanium (Ge), or silicon-germanium (SiGe), and here, the active and sacrificial layers ACL and SAL may be formed of different materials from each other.

The sacrificial layer SAL may be formed of at least one of materials having an etch selectivity with respect to the active layer ACL. For example, the active layers ACL may be formed of or include silicon (Si), and the sacrificial layers SAL may be formed of or include silicon germanium (SiGe). A germanium concentration of each of the sacrificial layers SAL may range from 10 at % to 30 at %.

Each of the sacrificial layers SAL may have a height in the third direction D3. The third direction D3 may not be parallel to both the first and second directions D1 and D2. For example, the third direction D3 may be a direction perpendicular to the substrate 100. A height of the lowermost one of the sacrificial layers SAL in the third direction D3 may be larger than a height of the others of the sacrificial layers SAL in the third direction D3. The height of the lowermost one of the sacrificial layers SAL in the third direction D3 may be 1.5 to 4.0 times (or 2.5 to 3.5 times) the height of the others of the sacrificial layers SAL in the third direction D3.

Mask patterns may be respectively formed on the first and second active regions AR1 and AR2 of the substrate 100. The mask pattern may be a line-or bar-shaped pattern that is extended in the second direction D2.

A patterning process using the mask patterns as an etch mask may be performed to form the trench TR defining a first active pattern PAP1 and a second active pattern PAP2. The first active pattern PAP1 may be formed on the first active region AR1. The second active pattern PAP2 may be formed on the second active region AR2. Each of the first and second active patterns PAP1 and PAP2 may be a vertically protruding portion of the substrate 100.

A stacking pattern STP may be formed on each of the first and second active patterns PAP1 and PAP2. The stacking pattern STP may include the active layers ACL and the sacrificial layers SAL which are alternately stacked. The stacking pattern STP may be formed along with the first and second active patterns PAP1 and PAP2, during the patterning process.

The device isolation layer ST may be formed to fill the trench TR. In detail, an insulating layer may be formed on a frontside surface of the substrate 100 to cover the first and second active patterns PAP1 and PAP2 and the stacking patterns STP. The device isolation layer ST may be formed by recessing the insulating layer until the stacking patterns STP are exposed.

The device isolation layer ST may be formed of or include at least one of insulating materials (e.g., silicon oxide). The stacking patterns STP may be placed on the device isolation layer ST and may be exposed to the outside of the device isolation layer ST. For example, the stacking patterns STP may protrude vertically above the device isolation layer ST.

Referring to FIGS. 10A and 10B, sacrificial patterns PP may be formed on the substrate 100 to cross the stacking patterns STP. Each of the sacrificial patterns PP may be a line-or bar-shaped pattern that is extended in the first direction D1. The sacrificial patterns PP may be arranged at a first pitch in the second direction D2.

In detail, the formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may be formed of or include polysilicon.

The formation of the sacrificial layer may include depositing the sacrificial layer to have a specific thickness on the frontside surface of the substrate 100. The sacrificial patterns PP may have a first thickness PPH which is determined by the specific thickness of the sacrificial layer. Here, the first thickness PPH may be a height of the sacrificial pattern PP measured from the stacking pattern STP. The first thickness PPH may correspond to the fourth gate height GH4 of the outer electrode PO4 described with reference to FIG. 5D. The first thickness PPH may be a vertical distance from a top surface of the uppermost one of the active layers ACL to the uppermost surface of the sacrificial pattern PP. For example, the first thickness PPH may range from 5.0 nm to 30.0 nm, and in particular, from 10.0 nm to 12.0 nm.

The height of the lowermost one of the sacrificial layers SAL in the third direction D3 may be defined as a second thickness SALH. That is, the second thickness SALH may correspond to the first gate height GHI of the first inner electrode PO1 previously described with reference to FIG. 5D. The second thickness SALH may be larger than the first thickness PPH. The second thickness SALH may be 1.5 to 4.0 times (or 2.5 to 3.5 times) the first thickness PPH. For example, the second thickness SALH may range from 7.5 nm to 120 nm, and in particular, from 12.5 nm to 105 nm.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. In an embodiment, the gate spacer GS may be a multi-layered structure including at least two layers.

Referring to FIGS. 11A to 11C, first recesses RS1 may be formed in the stacking pattern STP on the first active pattern PAP1. Second recesses RS2 may be formed in the stacking pattern STP on the second active pattern PAP2. During the formation of the first and second recesses RS1 and RS2, the device isolation layer ST may be further recessed at both sides of each of the first and second active patterns PAP1 and PAP2.

In detail, the first recesses RS1 may be formed by etching the stacking pattern STP on the first active pattern PAP1 using the hard mask patterns MP and the gate spacers GS as an etch mask. The first recess RS1 may be formed between a pair of the sacrificial patterns PP.

The first to third semiconductor patterns SP1, SP2, and SP3, which are sequentially stacked on a region between adjacent ones of the first recesses RS1, may be formed from the active layers ACL, respectively. The first to third semiconductor patterns SP1, SP2, and SP3 between adjacent ones of the first recesses RS1 may constitute the first channel pattern CH1.

The first recess RS1 may be formed between adjacent ones of the sacrificial patterns PP. A width of the first recess RS1 in the second direction D2 may decrease as a distance to the substrate 100 decreases.

The sacrificial layers SAL may be exposed by the first recess RS1. A selective etching process may be performed on the exposed sacrificial layers SAL. The etching process may include a wet etching process of selectively removing only silicon-germanium selectively. As a result of the etching process, each of the sacrificial layers SAL may be indented to form an indent region IDR. Due to the presence of the indent region IDR, the sacrificial layer SAL may have a concave side surface. An insulating layer may be formed in the first recess RS1 to fill the indent regions IDR. The first to third semiconductor patterns SP1, SP2, and SP3 and the sacrificial layers SAL, which are exposed by the first recess RS1, may be used as a seed layer for the insulating layer. The insulating layer may be grown as a crystalline dielectric layer, owing to the crystalline structure of the semiconductor materials of the first to third semiconductor patterns SP1, SP2, and SP3 and the sacrificial layers SAL.

The inner spacer ISP may be formed to fill the indent region IDR. In detail, the formation of the inner spacer ISP may include performing a wet etching process on the epitaxial dielectric layer until the side surfaces of the first to third semiconductor patterns SP1, SP2, and SP3 are exposed. Accordingly, the epitaxial dielectric layer may form the inner spacer ISP that is left in only the indent region IDR.

Referring back to FIGS. 11A to 11C, the second recesses RS2 in the stacking pattern STP on the second active pattern PAP2 may be formed by a method that is similar to a method of forming the first recesses RS1. A selective etching process may be performed on the sacrificial layers SAL exposed by the second recess RS2 to form indent regions IDE on the second active pattern PAP2. Due to the indent regions IDE, the second recess RS2 may have a wavy inner side surface. The inner spacers ISP may not be formed on the indent regions IDE on the second active pattern PAP2. The first to third semiconductor patterns SP1, SP2, and SP3 between adjacent ones of the second recesses RS2 may constitute the second channel pattern CH2.

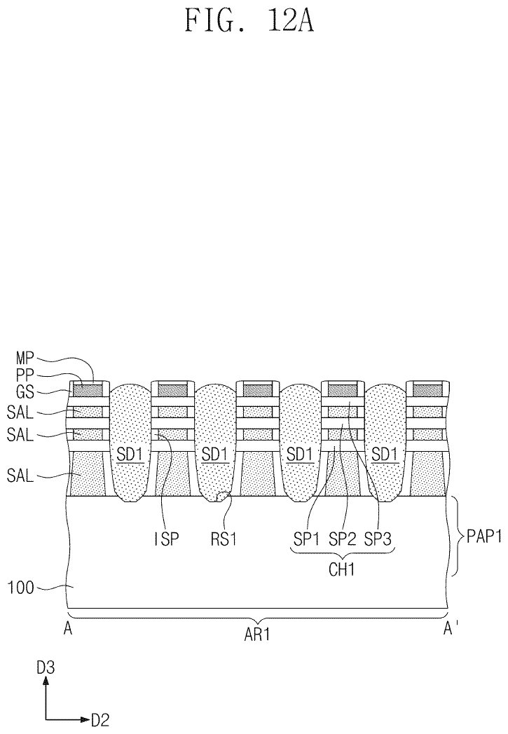

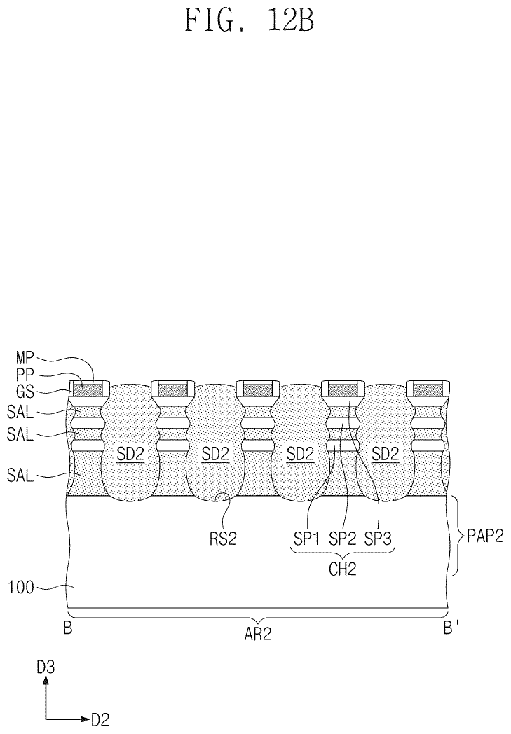

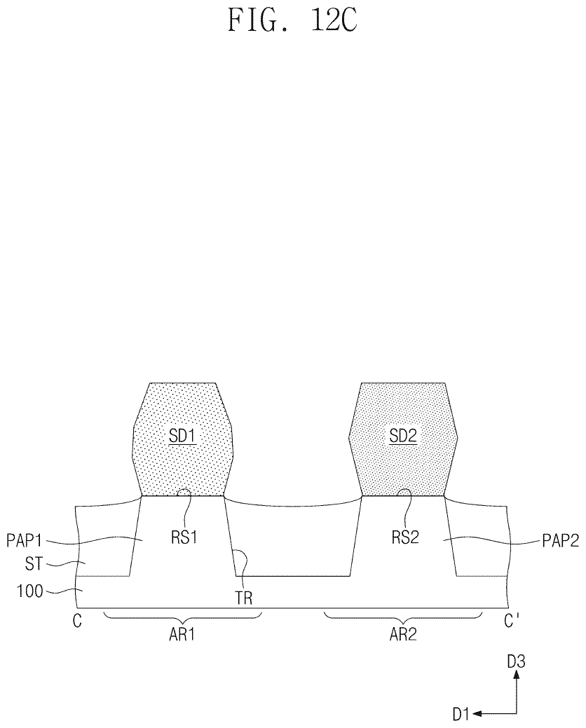

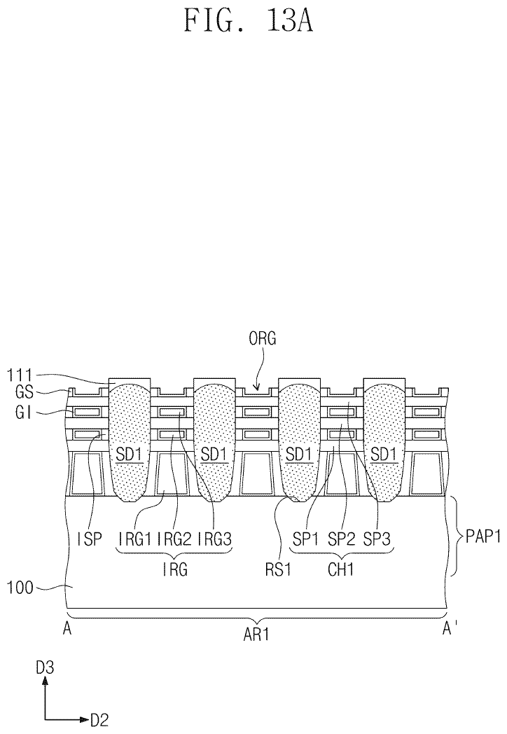

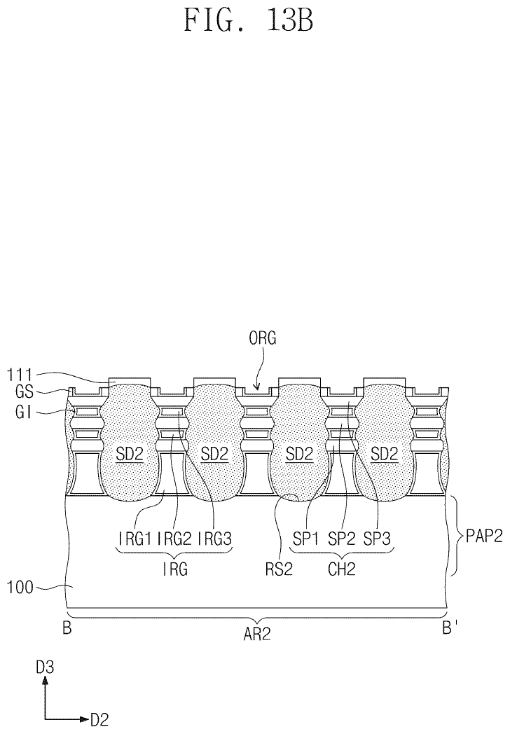

Referring to FIGS. 12A to 12C, the first source/drain patterns SD1 may be formed in the first recesses RS1, respectively. In detail, a SEG process, in which an inner surface of the first recess RS1 is used as a seed layer, may be performed to form an epitaxial layer filling the first recess RS1. The epitaxial layer may be grown using the first to third semiconductor patterns SP1, SP2, and SP3 and the substrate 100, which are exposed by the first recess RS1, as the seed layer. In an embodiment, the SEG process may include a chemical vapor deposition (CVD) process or a molecular beam epitaxy (MBE) process.

In an embodiment, the first source/drain pattern SD1 may include the same semiconductor element (e.g., Si) as the substrate 100. During the formation of the first source/drain pattern SD1, the first source/drain pattern SD1 may be doped in-situ with n-type impurities (e.g., phosphorus, arsenic, or antimony). Alternatively, impurities may be injected into the first source/drain pattern SD1, after the formation of the first source/drain pattern SD1.

The second source/drain patterns SD2 may be formed in the second recesses RS2, respectively. In detail, the second source/drain pattern SD2 may be formed by a SEG process using an inner surface of the second recess RS2 as a seed layer.

In an embodiment, the second source/drain pattern SD2 may be formed of or include a semiconductor material (e.g., SiGe) whose lattice constant is greater than that of a semiconductor material of the substrate 100. During the formation of the second source/drain pattern SD2, the second source/drain pattern SD2 may be doped in-situ with p-type impurities (e.g., boron, gallium, or indium). Alternatively, impurities may be injected into the second source/drain pattern SD2, after the formation of the second source/drain pattern SD2.

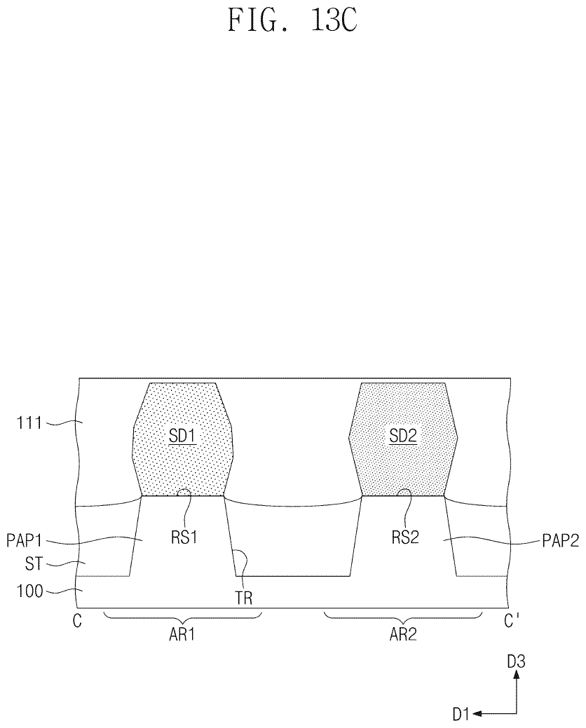

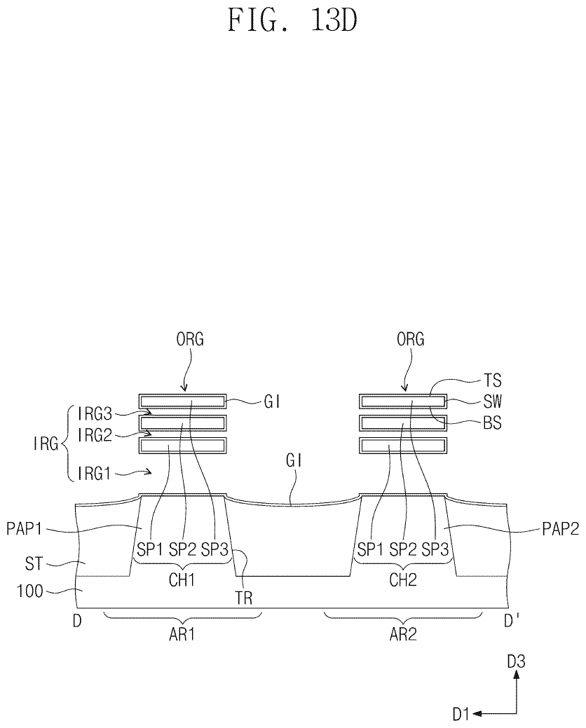

Referring to FIGS. 13A to 13D, a preliminary interlayer insulating layer 111 may be formed to cover the first and second source/drain patterns SD1 and SD2, the hard mask patterns MP, and the gate spacers GS. In an embodiment, the preliminary interlayer insulating layer 111 may include a silicon oxide layer.

The preliminary interlayer insulating layer 111 may be planarized to expose the top surfaces of the sacrificial patterns PP. The planarization of the preliminary interlayer insulating layer 111 may be performed using an etch-back process or a chemical mechanical polishing (CMP) process. All the hard mask patterns MP may be removed during the planarization process.

In an embodiment, the exposed sacrificial patterns PP may be selectively removed. As a result of the removal of the sacrificial patterns PP, an outer region ORG exposing the first and second channel patterns CH1 and CH2 may be formed (e.g., see FIG. 13D). The removal of the sacrificial patterns PP may include a wet etching process which is performed using an etching solution capable of selectively etching polysilicon.

Inner regions IRG may be formed by selectively removing the sacrificial layers SAL, which are exposed through the outer region ORG (e.g., see FIG. 13D). In detail, a process of selectively etching the sacrificial layers SAL may be performed to leave the first to third semiconductor patterns SP1, SP2, and SP3 and to remove only the sacrificial layers SAL. An etch recipe for the etching process may be chosen to etch a layer (e.g., a silicon germanium layer), which is formed to have a relatively high germanium concentration, at a high etch rate. For example, the etching process may be chosen to have a high etch rate to a silicon germanium layer whose germanium concentration is higher than 10 at %.

During the etching process, the sacrificial layers SAL on the first and second active regions AR1 and AR2 may be removed. The etching process may be a wet etching process. An etchant material, which is used in the etching process, may be chosen to quickly remove the sacrificial layer SAL having a relatively high germanium concentration. A portion of the gate spacer GS may be removed, during the etching process. As a result of the loss of the gate spacer GS, a top surface of the preliminary interlayer insulating layer 111 may be located at a level higher than a top surface of the gate spacer GS.

Referring back to FIG. 13D, the first to third semiconductor patterns SP1, SP2, and SP3, which are stacked on each of the first and second active patterns PAP1 and PAP2, may be left, as a result of the selective removal of the sacrificial layers SAL. Empty regions, which are formed by removing the sacrificial layers SAL, may form first to third inner regions IRG1, IRG2, and IRG3, respectively.

In detail, the first inner region IRG1 may be formed between the active pattern PAP1 or PAP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3. A height of the first inner region IRG1 in the third direction D3 may be larger than a height of each of the second and third inner regions IRG2 and IRG3 in the third direction D3.

Referring back to FIGS. 13A to 13D, the gate insulating layer GI may be formed on the exposed first to third semiconductor patterns SP1, SP2, and SP3. The gate insulating layer GI may be formed to enclose each of the first to third semiconductor patterns SP1, SP2, and SP3. For example, the gate insulating layer GI may be formed on a top surface TS, side surfaces SW, and a bottom surface BS of each of the first to third semiconductor patterns SP1, SP2, and SP3. The gate insulating layer GI may be formed in each of the first to third inner regions IRG1, IRG2, and IRG3. The gate insulating layer GI may be formed in the outer region ORG.

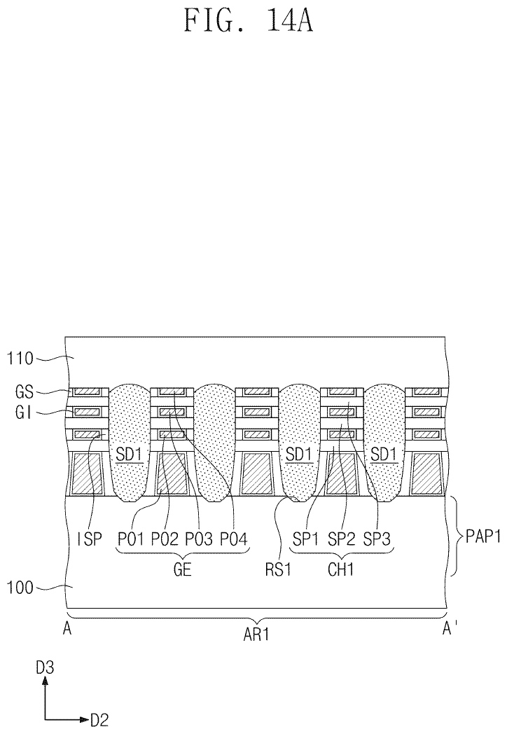

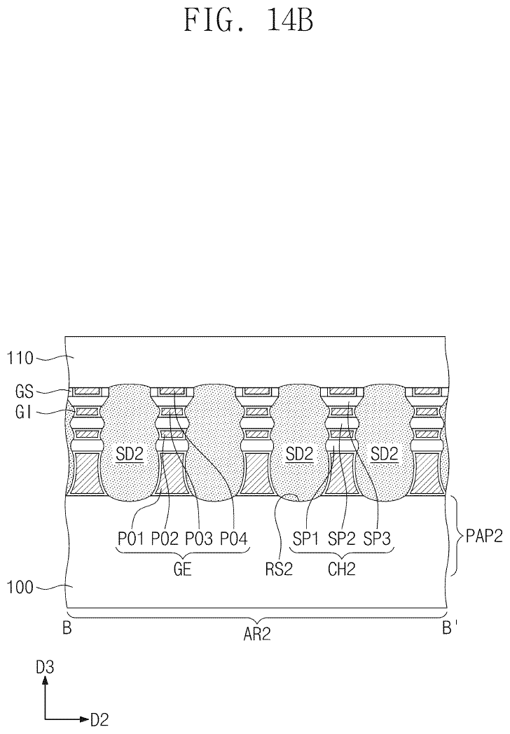

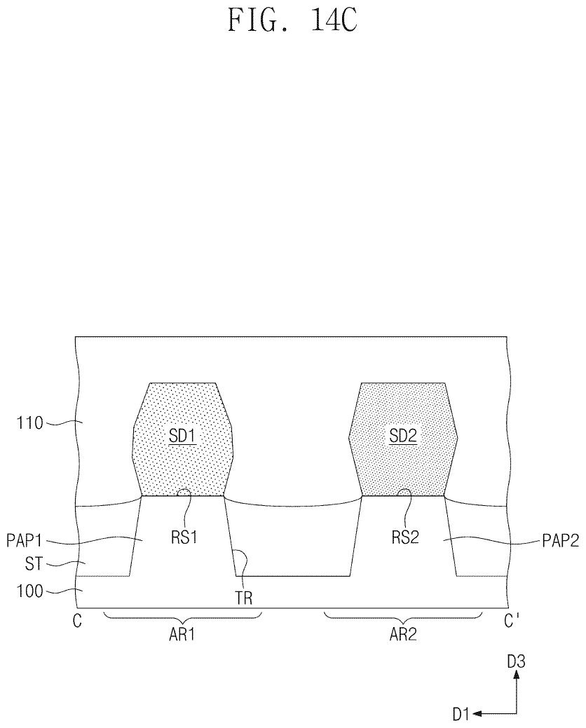

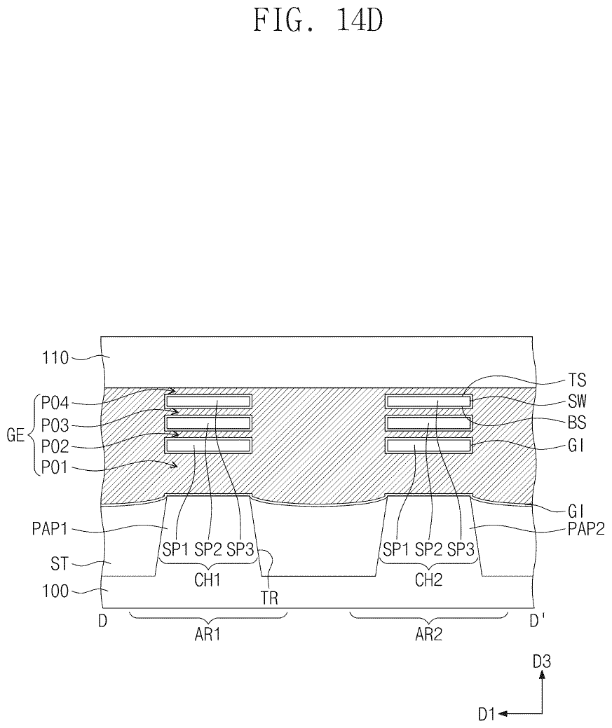

Referring to FIGS. 14A to 14D, the gate electrode GE may be formed on the gate insulating layer GI. In detail, the gate electrode GE may include the first to third inner electrodes PO1, PO2, and PO3, which are respectively formed in the first to third inner regions IRG1, IRG2, and IRG3, and the outer electrode PO4, which is formed in the outer region ORG.

In detail, the formation of the gate electrode GE may include forming a first metal layer in the first to third inner regions IRG1, IRG2, and IRG3 and the outer region ORG, forming a second metal layer on the first metal layer, and performing a CMP process on the first and second metal layers using the preliminary interlayer insulating layer 111 as a stopper. The first metal layer may include a metal nitride layer, and the second metal layer may include a metal layer with low resistance.

The formation of the first and second metal layers may include depositing the first and second metal layers to cover the gate insulating layer GI, the preliminary interlayer insulating layer 111, and the top surface of the gate spacer GS. The CMP process on the first and second metal layers may be performed to remove the first and second metal layers using slurry.

Referring back to FIGS. 14A to 14D, the first interlayer insulating layer 110 may be formed on the outer electrode PO4, the gate insulating layer GI, the gate spacer GS, and the preliminary interlayer insulating layer 111. The first interlayer insulating layer 110 may include the same material as the preliminary interlayer insulating layer 111. In an embodiment, the first interlayer insulating layer 110 may include a silicon oxide layer.

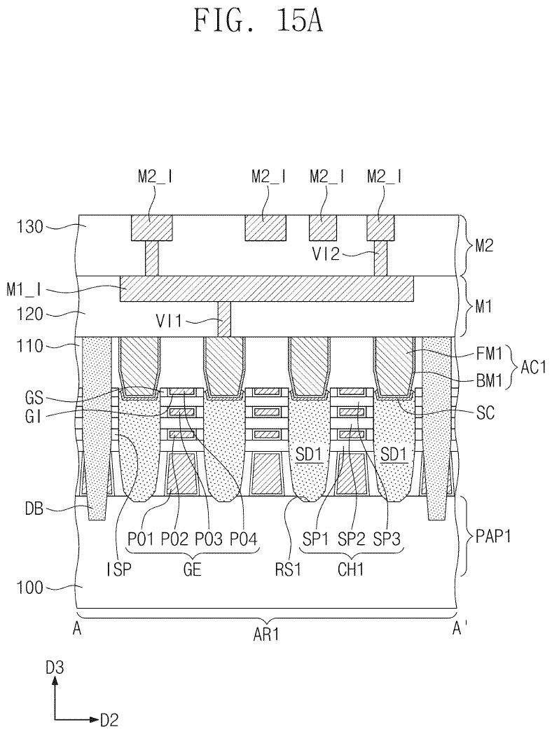

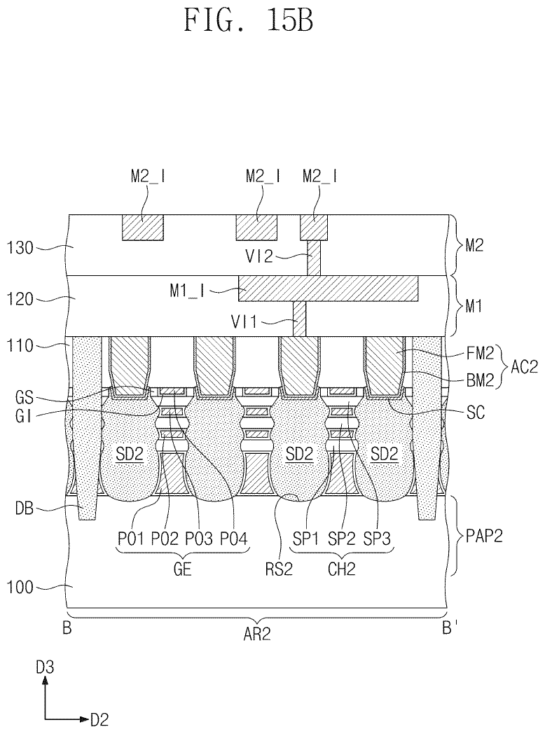

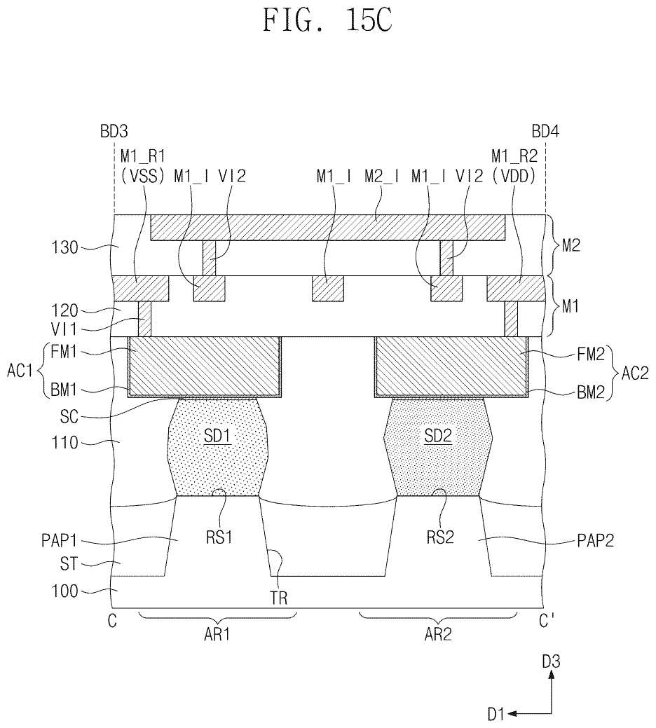

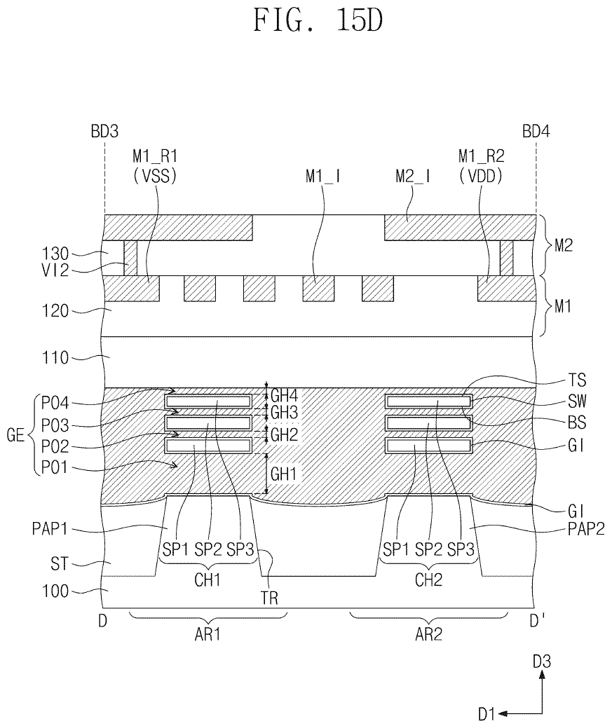

Referring to FIGS. 15A to 15D, an etch mask may be deposited on the first interlayer insulating layer 110, and then, first and second recess regions penetrating the first interlayer insulating layer 110 may be formed using the etch mask. In an embodiment, the first and second recess regions may be formed by a dry etching process.

The first recess region may penetrate the first interlayer insulating layer 110 and may be extended to an upper portion of the first source/drain pattern SD1. For example, the first recess region may include a portion that is inserted into the first source/drain pattern SD1. The second recess region may penetrate the first interlayer insulating layer 110 and may be extended to an upper portion of the second source/drain pattern SD2. For example, the second recess region may include a portion that is inserted into the second source/drain pattern SD2.

The first and second active contacts AC1 and AC2, which are electrically connected to the first and second source/drain patterns SD1 and SD2, may be formed to penetrate the first interlayer insulating layer 110. That is, the first and second active contacts AC1 and AC2 may be formed on the first and second recess regions, respectively.

The formation of each of the first and second active contacts AC1 and AC2 may include forming the first and second barrier patterns BM1 and BM2 and forming the first and second conductive patterns FM1 and FM2 on the first and second barrier patterns BM1 and BM2. The first and second barrier patterns BM1 and BM2 may be formed conformally and may include a metal layer and a metal nitride layer. The first and second conductive patterns FM1 and FM2 may include at least one of low resistance metals.

The division structures DB may be respectively formed on the first and second borders BD1 and BD2 of the single height cell SHC. The division structure DB may penetrate the first interlayer insulating layer 110 and the gate electrode GE and may be extended into the active pattern PAP1 or PAP2. The division structure DB may be formed of or include an insulating material (e.g., silicon oxide or silicon nitride). In an embodiment, the division structure DB may include a metallic material.

The second interlayer insulating layer 120 may be formed on the first and second active contacts AC1 and AC2. The first metal layer M1 may be formed in the second interlayer insulating layer 120. The third interlayer insulating layer 130 may be formed on the second interlayer insulating layer 120. The second metal layer M2 may be formed in the third interlayer insulating layer 130.

Referring back to FIG. 15D, the first inner electrode PO1 may have the first gate height GH1. The second inner electrode PO2 may have the second gate height GH2. The third inner electrode PO3 may have the third gate height GH3. The outer electrode PO4 may have the fourth gate height GH4.

The first gate height GH1 may be larger than the fourth gate height GH4. The first gate height GH1 may be 1.5 to 4.0 times (or 2.5 to 3.5 times) the fourth gate height GH4. The fourth gate height GH4 may be substantially equal to the second and third gate heights GH2 and GH3. In an embodiment, although not shown, the first gate height GH1 may be equal to the fourth gate height GH4.

For example, the first gate height GH1 may range from 7.5 nm to 120 nm, and in particular, from 12.5 nm to 105 nm. Each of the second, third, and fourth gate heights GH2, GH3, and GH4 may range from 5.0 nm to 30.0 nm, and in particular, from 10.0 nm to 12.0 nm.

In the semiconductor device according to an embodiment of inventive concepts, since the first inner electrode PO1 of the gate electrode GE is formed to have the gate height GH1 larger than the gate height GH4 of the outer electrode PO4, the back-side gate contact BGC may be connected to the gate electrode GE. That is, by reducing a density of the contact patterns, it may be possible to limit and/or prevent a short circuit from being formed between the gate and the active contact. Accordingly, it may be possible to limit and/or prevent a leakage current from being formed in a transistor.

In addition, since the source/drain pattern is formed in an over-grown manner, it may be possible to secure a process margin, which is related to the loss of the source/drain pattern, in subsequent etching and cleaning processes. Accordingly, it may be possible to improve the efficiency in a process of fabricating a semiconductor device.

According to an embodiment of inventive concepts, by optimizing a height of the gate electrode, it may be possible to improve the electrical and reliability characteristics of the semiconductor device and the efficiency of the fabrication process.

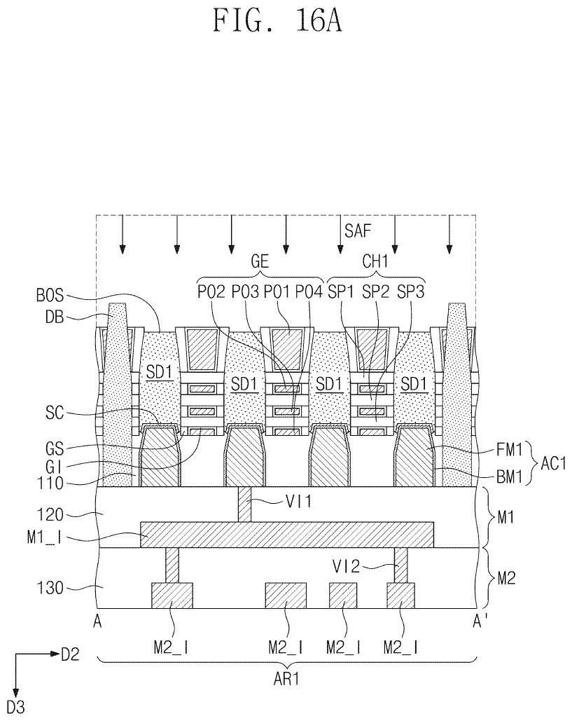

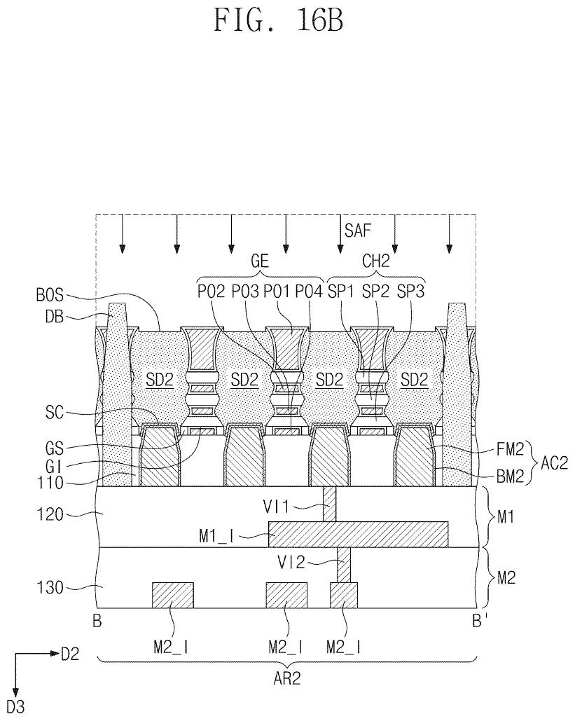

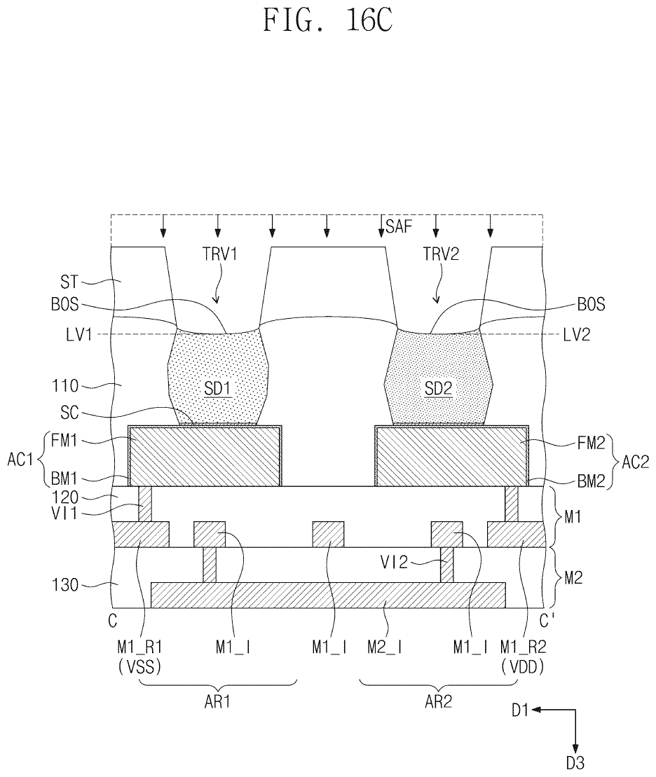

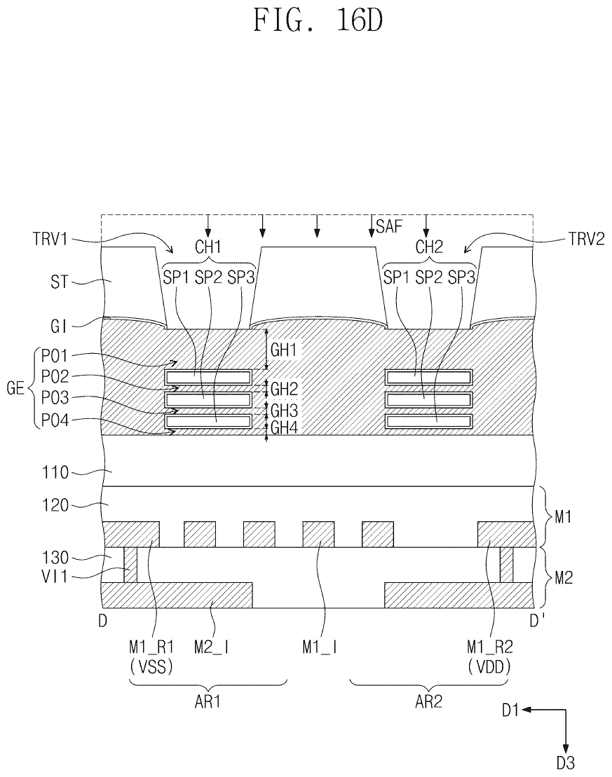

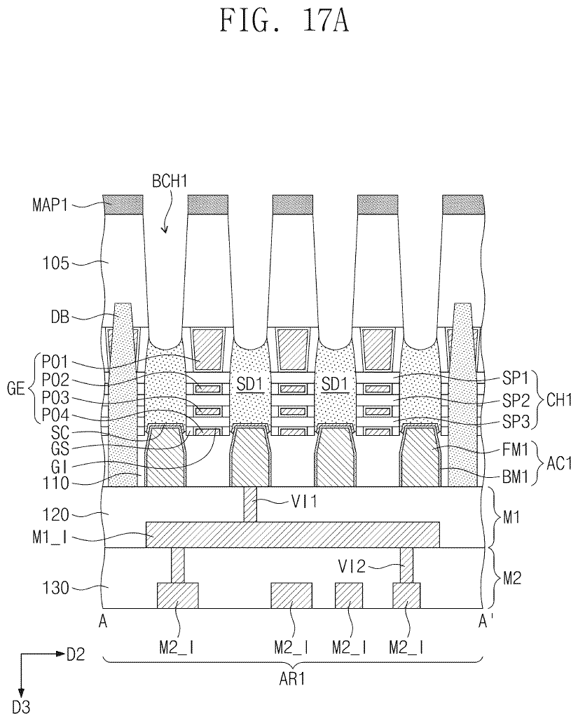

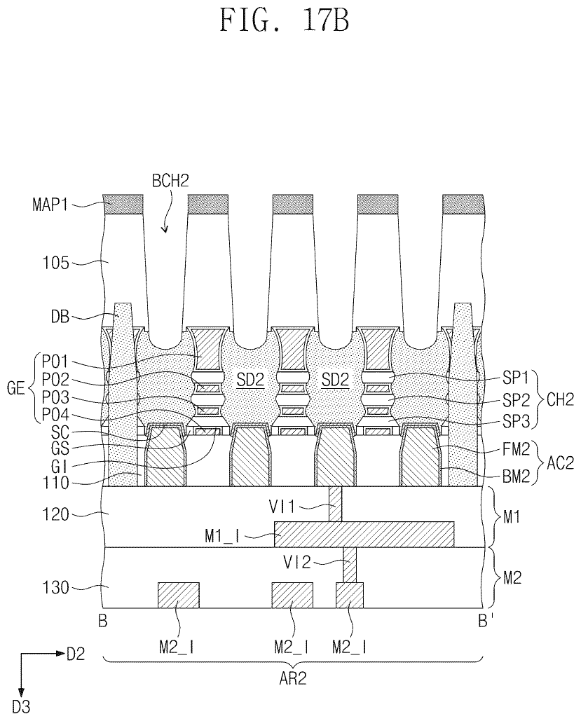

Referring to FIGS. 16A to 16D, if a BEOL process is finished, the semiconductor substrate 100 may be inverted such that a bottom surface of the semiconductor substrate 100 is exposed. The exposed semiconductor substrate 100 may be completely removed.

In an embodiment, the removal of the semiconductor substrate 100 may include performing a planarization process SAF on the bottom surface of the semiconductor substrate 100 to reduce a thickness of the semiconductor substrate 100, performing a cleaning process to selectively remove silicon (Si) on the semiconductor substrate 100, and performing a first etching process to selectively remove silicon (Si) in the first and second active patterns PAP1 and PAP2. The cleaning process may be performed to expose the device isolation layer ST. The first etching process may be a dry etching process or a wet etching process.

As a result of the removal of the semiconductor substrate 100, a first back-side trench TRV1 may be formed in a region where was occupied by the first active pattern PAP1. As a result of the removal of the semiconductor substrate 100, a second back-side trench TRV2 may be formed in a region where was occupied by the second active pattern PAP2 (e.g., see FIG. 16C).

In an embodiment, the removal of the semiconductor substrate 100 may be performed to slightly remove lower portions of the first and second source/drain patterns SD1 and SD2. In detail, the lower portions of the first and second source/drain patterns SD1 and SD2 may be recessed by the first etching process. Accordingly, each of the first and second source/drain patterns SD1 and SD2 may be formed to have a concave bottom BOS (e.g., see FIG. 16C). A level of the concave bottom BOS of the first source/drain pattern SD1 in the third direction D3 may be defined as a first lower level LV1. A level of the concave bottom BOS of the second source/drain pattern SD2 in the third direction D3 may be defined as a second lower level LV2. The first and second lower levels LV1 and LV2 may be located at the same level in the third direction D3.

In an embodiment, the removal of the semiconductor substrate 100 may be performed to slightly remove a lower portion of the gate electrode GE. In detail, a portion of the gate insulating layer GI and the lower portion of the gate electrode GE, which are exposed by the first etching process, may be recessed. Accordingly, a lower portion of the first inner electrode PO1 of the gate electrode GE may be exposed to the outside (e.g., see FIG. 16D).

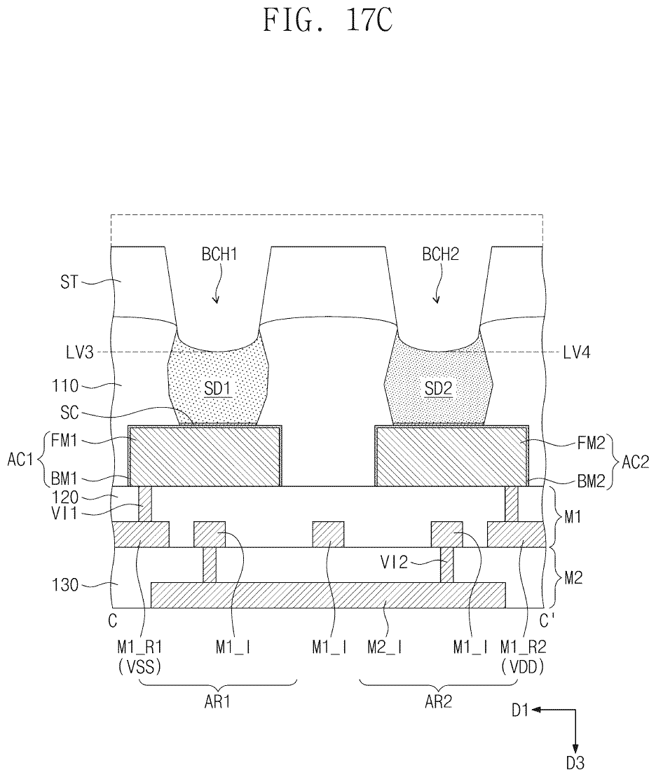

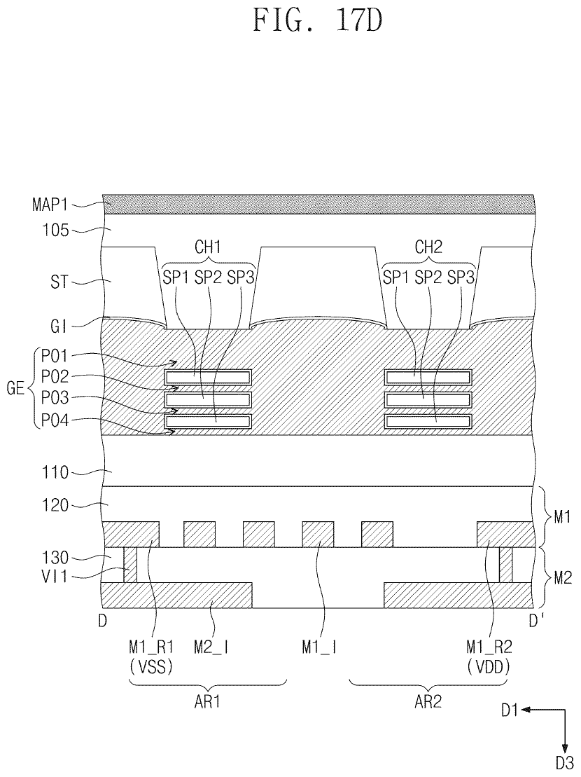

Referring to FIGS. 17A to 17D, the substrate 105 may be formed by filling an empty region, which is formed by removing the semiconductor substrate 100, with an insulating material. The substrate 105 may include a silicon-based insulating layer. For example, the substrate 105 may include a silicon nitride layer.

First mask patterns MAP1 may be formed on the substrate 105. The first mask patterns MAP1 may be formed through a photolithography process. The first mask patterns MAP1 may be line-or bar-shaped patterns that are extended in the first direction D1.

First back-side holes BCH1 may be formed on the first active region AR1 by performing a second etching process on the substrate 105 using the first mask patterns MAP1 as an etch mask. Second back-side holes BCH2 may be formed on the second active region AR2 by performing the second etching process using the first mask patterns MAP1 as an etch mask. The second etching process may be a dry etching process. The second etching process may be an anisotropic etching process.

In the second etching process, an etchant may slightly remove the first and second source/drain patterns SD1 and SD2 through the first and second back-side trenches TRV1 and TRV2. For example, lower portions of the first and second source/drain patterns SD1 and SD2 may be further recessed by the etchant. Accordingly, each of the first and second source/drain patterns SD1 and SD2 may be formed to have a concave bottom (e.g., see FIG. 17C).

After the second etching process, a level of the concave bottom of the first source/drain pattern SD1 in the third direction D3 may be defined as a third lower level LV3. After the second etching process, a level of the concave bottom of the second source/drain pattern SD2 in the third direction D3 may be defined as a fourth lower level LV4. The third and fourth lower levels LV3 and LV4 may be located at the same level in the third direction D3. Each of the third and fourth lower levels LV3 and LV4 may be lower than the first and second lower levels LV1 and LV2 in the third direction D3.

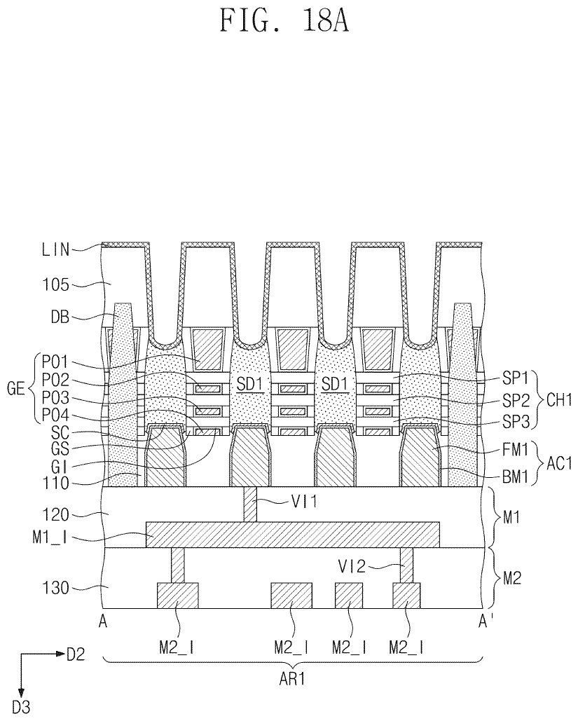

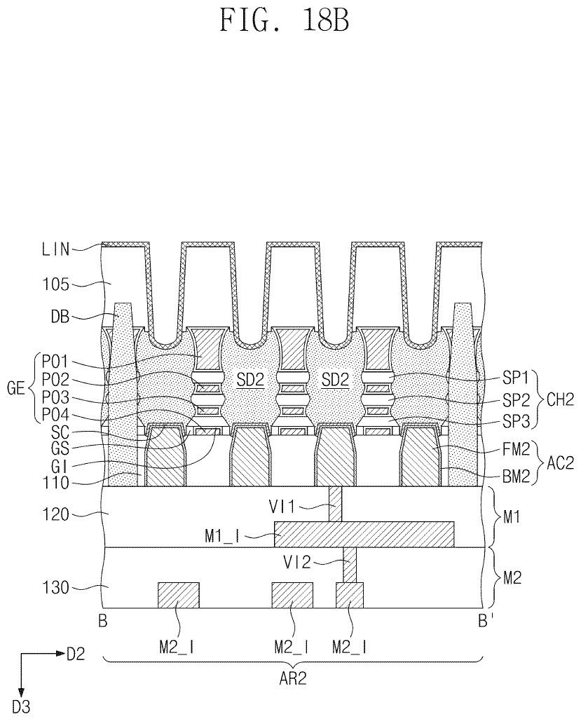

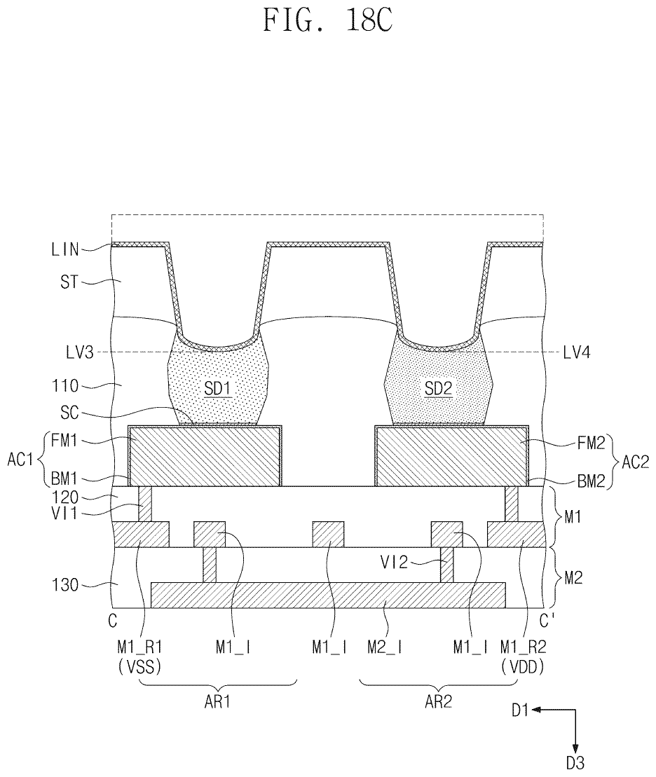

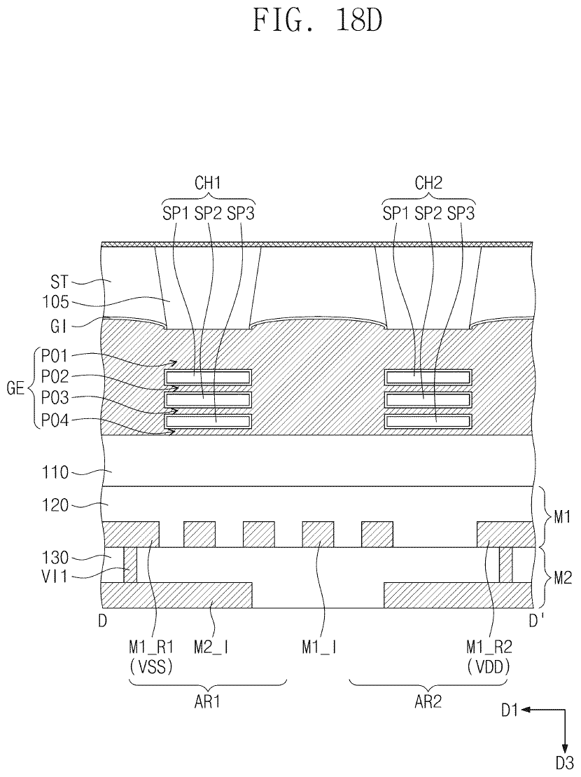

Referring to FIGS. 18A to 18D, a strip process or an ashing process may be performed on the first mask patterns MAP1 to remove the first mask patterns MAP1. After the removal of the first mask patterns MAP1, a CMP process may be performed on the exposed substrate 105. The CMP process may be performed using the device isolation layer ST as a stopper. A bottom surface of the device isolation layer ST may be substantially coplanar with a bottom surface of the substrate 105, which is located below the gate electrode GE (e.g., see FIG. 18D).

Since the back-side gate contact BGC is formed through the CMP process, a volume of a shallow trench isolation (STI) may be reduced. That is, it may be possible to limit and/or prevent a floating body effect in the transistor. Accordingly, it may be possible to improve the electric characteristics of the semiconductor device.

Referring back to FIGS. 18A to 18D, the liner layer LIN may be formed on an inner side surface of each of each of the first and second back-side holes BCH1 and BCH2, bottom surfaces of the first and second source/drain patterns SD1 and SD2, the substrate 105, and the device isolation layer ST. The liner layer LIN may have a uniform thickness. The liner layer LIN may be formed of an oxide-based material (e.g., TiO). The liner layer LIN may be formed of or include a material having an etch selectivity with respect to the substrate 105 and a back-side insulating layer ILD to be described below. The liner layer LIN may be formed of or include a material that is harder than a silicon oxide layer. A composition ratio of titanium oxide of the liner layer LIN may be adjusted to increase the hardness of the liner layer LIN. In an embodiment, the liner layer LIN may be formed such that a titanium content is higher than an oxide content.

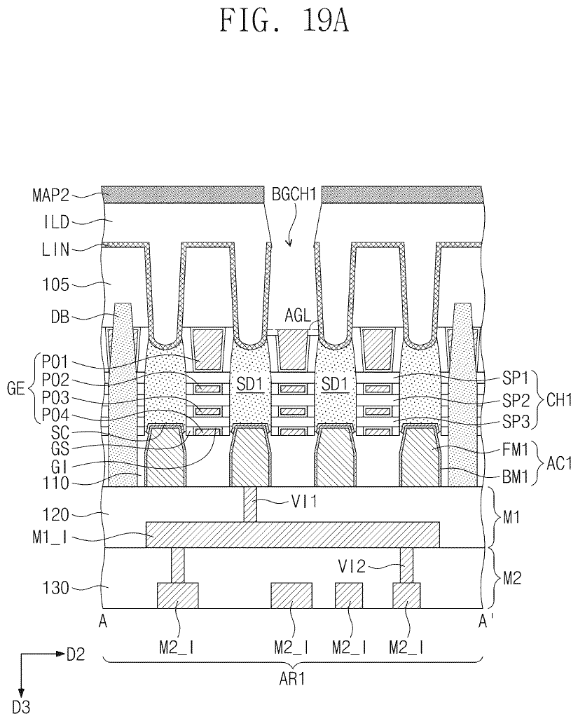

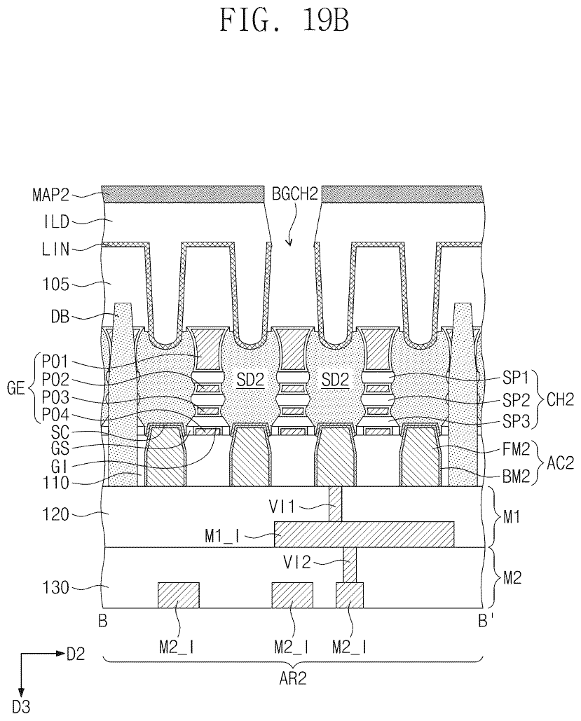

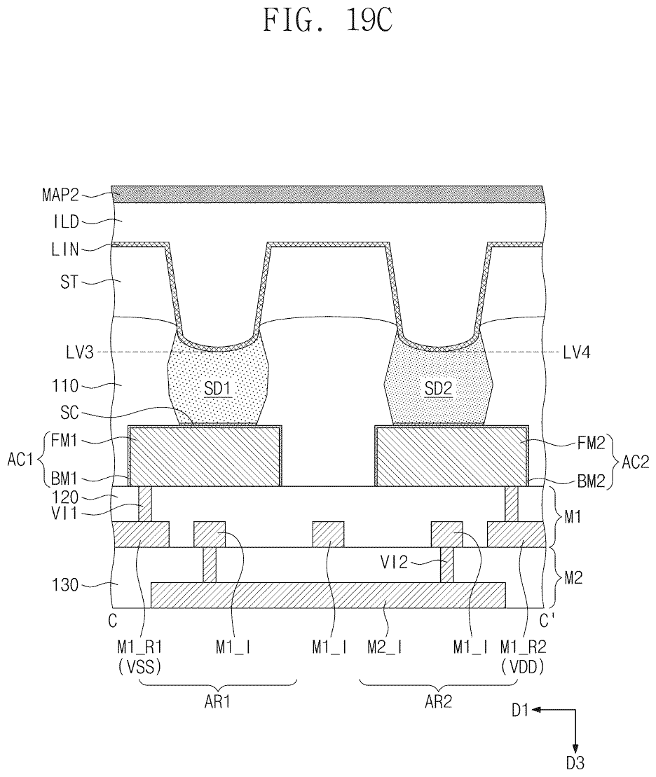

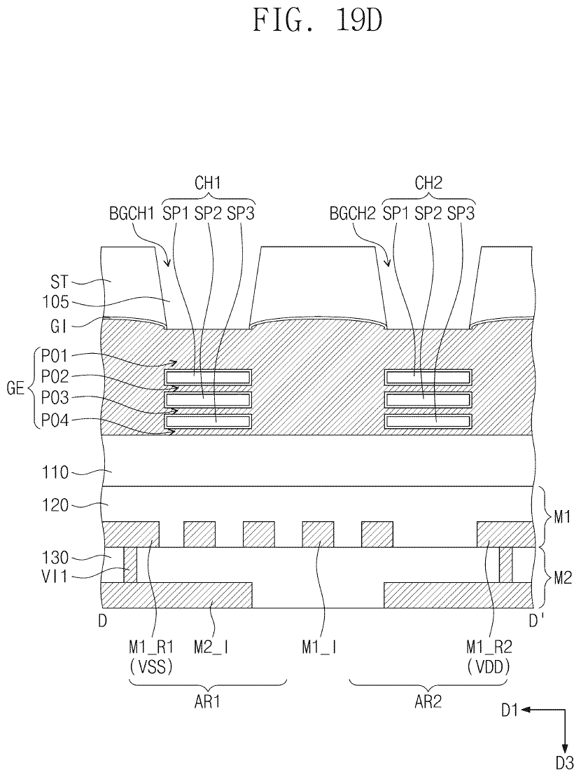

Referring to FIGS. 19A to 19D, the back-side insulating layer ILD may be formed by forming an insulating material on the liner layer LIN. The back-side insulating layer ILD may include a silicon-based insulating layer. For example, the back-side insulating layer ILD may include a silicon oxide layer.

Second mask patterns MAP2 may be formed on the back-side insulating layer ILD. The second mask patterns MAP2 may be formed through a photolithography process. The second mask patterns MAP2 may be line-or bar-shaped patterns that are extended in the second direction D2.

A first back-side gate contact hole BGCH1 may be formed on the first active region AR1 by performing a third etching process, in which the second mask patterns MAP2 are used as an etch mask, on the back-side insulating layer ILD. A second back-side gate contact hole BGCH2 may be formed on the second active region AR2 by performing the third etching process, in which the second mask patterns MAP2 are used as the etch mask, on the back-side insulating layer ILD. The third etching process may be a dry etching process. For example, the third etching process may be an anisotropic etching process.

In an embodiment, each of the first and second back-side gate contact holes BGCH1 and BGCH2 in the back-side insulating layer ILD may have a decreasing width in the second direction D2.

The liner layer LIN may have an etch selectivity with respect to the substrate 105 and the back-side insulating layer ILD and may include a material that is harder than the substrate 105 and the back-side insulating layer ILD. In this case, the liner layer LIN may not be removed by an etchant of the third etching process. Accordingly, a portion of the substrate 105, which is enclosed by the liner layer LIN, may be removed by the third etching process. That is, as a vertical level is lowered, each of the first and second back-side gate contact holes BGCH1 and BGCH2, which are enclosed by the liner layer LIN, may have an increasing width in the second direction D2. As a vertical level is lowered, the widths of the first and second back-side gate contact holes BGCH1 and BGCH2 in the second direction D2 may gradually decrease and then increase.

Each of the first and second back-side gate contact holes BGCH1 and BGCH2 may expose the gate electrode GE, the gate insulating layer GI, and the inner spacer ISP. In detail, each of the first and second back-side gate contact holes BGCH1 and BGCH2 may expose the first inner electrode PO1 of the gate electrode GE, the gate insulating layer GI, and the inner spacer ISP.

An angle between the bottom surface of the first inner electrode PO1 and the side surface of the liner layer LIN, which are exposed through the first back-side gate contact hole BGCH1, may be an acute angle. The acute angle may range from 45° to 90°.

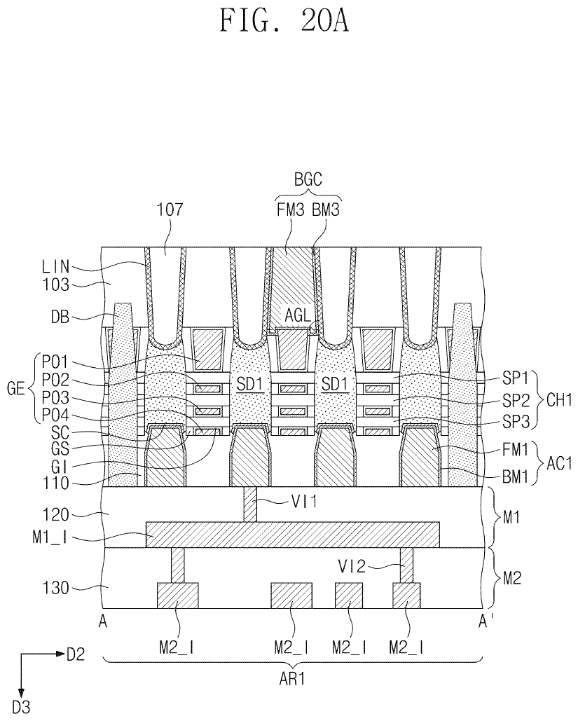

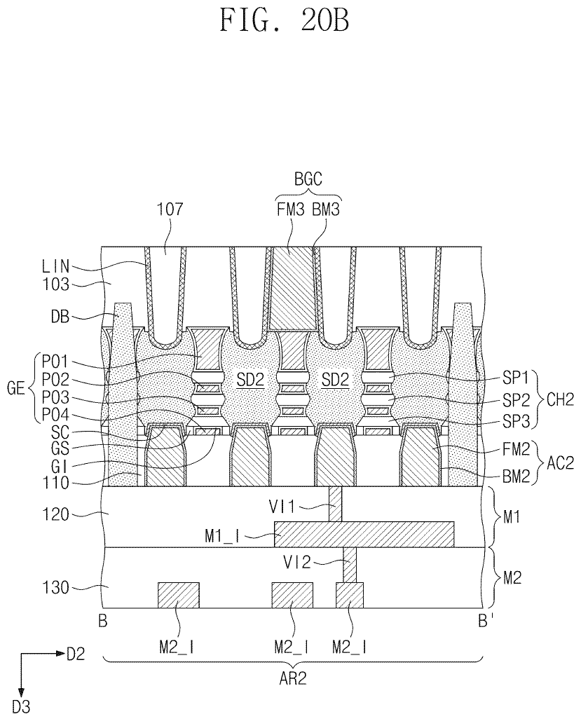

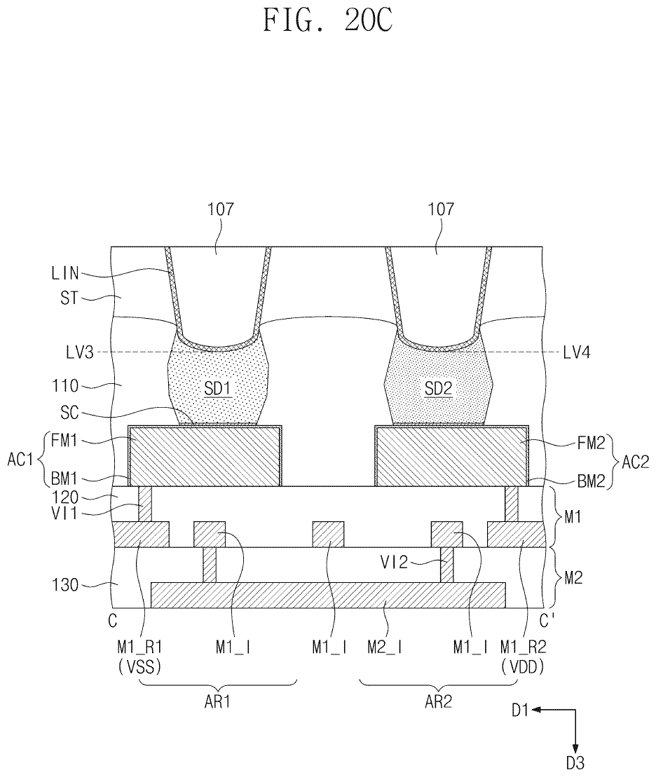

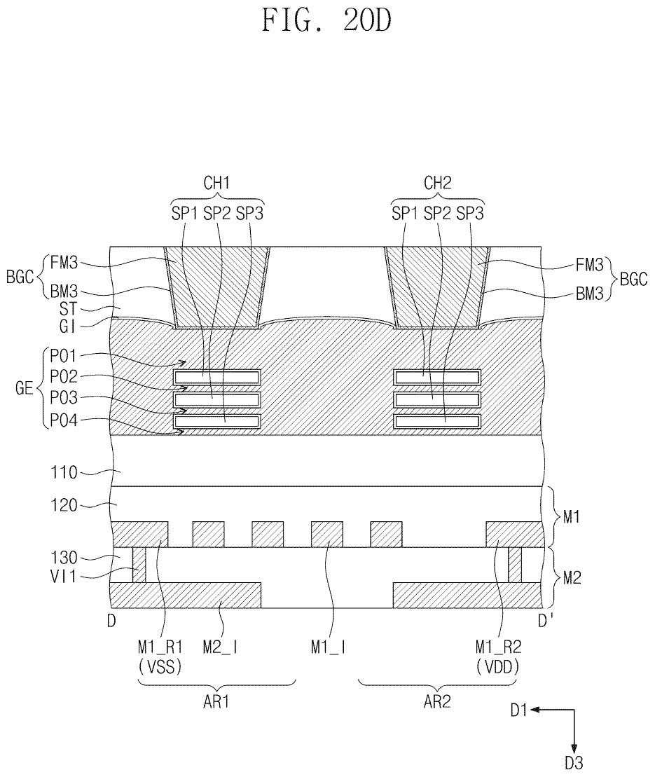

Referring to FIGS. 20A to 20D, a strip process or an ashing process may be performed on the second mask patterns MAP2 to remove the second mask patterns MAP2. After the removal of the second mask patterns MAP2, the back-side gate contact BGC may be formed in each of the first and second back-side gate contact holes BGCH1 and BGCH2. The back-side gate contact BGC may be formed to penetrate the base pattern 103 of the substrate 105 and may be electrically connected to the gate electrode GE. In detail, the back-side gate contact BGC may be in contact with the bottom surface of the first inner electrode PO1 of the gate electrode GE.

The formation of the back-side gate contacts BGC may include forming the third barrier pattern BM3 and forming the third conductive pattern FM3 on the third barrier pattern BM3. The third barrier pattern BM3 may be formed conformally and may include a metal layer and a metal nitride layer. The third conductive pattern FM3 may include a low resistance metal.

In detail, the formation of the back-side gate contacts BGC may include forming the third barrier pattern BM3, forming the third conductive pattern FM3 on the third barrier pattern BM3, and performing a CMP process on the third barrier pattern BM3 and the third conductive pattern FM3 using the bottom surface of the substrate 105 as a stopper. In the CMP process, slurry may be used to remove the third barrier pattern BM3 and the third conductive pattern FM3.

A portion of the substrate 105 and the back-side insulating layer ILD, which are left after the CMP process, may be referred to as the base pattern 103 and the basal dielectric pattern 107, respectively. The basal dielectric pattern 107 and the liner layer LIN may be defined as the insulating structure DST. After the CMP process, a bottom surface of the base pattern 103, a bottom surface of the insulating structure DST, and a bottom surface of the back-side gate contact BGC may be substantially coplanar with each other.

Referring back to FIGS. 5A to 5D, a backside interlayer insulating layer 210 may be formed below the substrate 105. The back-side metal layer BM may be provided in the backside interlayer insulating layer 210. For example, the back-side metal layer BM may include the backside interconnection line BM_I. The back-side metal layer BM may further include the backside via BVI. The backside via BVI may be provided below the back-side gate contact BGC. The back-side gate contact BGC and the backside interconnection line BM_I may be electrically connected to each other through the backside via BVI.

The interconnection line and the via of the back-side metal layer BM may be formed by separate processes. That is, each of the interconnection line and the via of the back-side metal layer BM may be formed by a single damascene process. The semiconductor device according to the present embodiment may be fabricated using a sub-20 nm process.

The power delivery network layer PDN may be formed below the back-side metal layer BM. The power delivery network layer PDN may include a plurality of lower interconnection lines, which are electrically connected to the backside interconnection lines BM_I. In an embodiment, the power delivery network layer PDN may include an interconnection network, which is used to apply a gate voltage (Gate on/off) to the backside interconnection lines BM_I.

According to an embodiment of inventive concepts, a semiconductor device may include a gate contact, which is formed to penetrate a backside surface of a substrate and is connected to a gate pattern of a transistor (e.g., a three-dimensional field effect transistor), and in this case, it may be possible to lower a pattern density (e.g., a metal route density) of a metal line layer on a frontside surface of the substrate. Accordingly, it may be possible to reduce technical difficulty in a metal patterning process of forming an interconnection pattern and to increase an operation speed of a transistor. Thus, the semiconductor device may be fabricated to have improved electrical and reliability characteristics.

In a semiconductor device according to an embodiment of inventive concepts, a height of a gate pattern and a height of a source/drain pattern may be optimized to suppress a short phenomenon between the gate pattern and the contact. In addition, it may be possible to secure a process margin in a process of forming the gate pattern and the source/drain pattern. For example, it may be possible to reduce the technical difficulty in the process of forming the gate pattern, the source/drain pattern, and the contact and to reduce the leakage current from the transistor to the substrate. Thus, the electrical and reliability characteristics of the semiconductor device may be improved.

While example embodiments of inventive concepts have been particularly shown and described, it will be understood by one of ordinary skill in the art that variations in form and detail may be made therein without departing from the spirit and scope of the attached claims.

What is claimed is:

1. A semiconductor device, comprising:
a substrate including an insulating structure;
a back-side metal layer below the substrate;
a source/drain pattern on the insulating structure;
a channel pattern connected to the source/drain pattern, the channel pattern including a plurality of semiconductor patterns, which are vertically stacked and spaced apart from each other;
a gate electrode on the plurality of semiconductor patterns, the gate electrode including inner electrodes and an outer electrode, the inner electrodes being between adjacent ones of the plurality of the semiconductor patterns, and the outer electrode being on an uppermost one of the semiconductor patterns; and
a back-side gate contact penetrating the substrate and electrically connecting the back-side metal layer to the gate electrode, wherein
the back-side gate contact includes a first surface and a second surface,
the first surface of the back-side gate contact is in contact with a bottom surface of the gate electrode,
the second surface of the back-side gate contact is in contact with a side surface of the insulating structure, and
an angle between the first surface of the back-side gate contact and the second surface of the back-side gate contact is an acute angle.

2. The semiconductor device of claim 1, wherein the angle between the first surface of the back-side gate contact and the second surface of the back-side gate contact ranges from 45° to 90°.

3. The semiconductor device of claim 1, further comprising:
an inner spacer between the source/drain pattern and the gate electrode, wherein
the substrate comprises a plurality of insulating structures,
the back-side gate contact comprises a conductive pattern and a barrier pattern on the conductive pattern,
the conductive pattern comprises a body portion and an edge portion,
the body portion of the conductive pattern is between the plurality of insulating structures, and
the edge portion conductive protrudes from the body portion conductive toward the inner spacer.

4. The semiconductor device of claim 3, wherein
the barrier pattern extends from a first side surface of the body portion of the conductive pattern to a second side surface of the body portion of the conductive pattern over each of a top surface of the edge portion of the conductive pattern and a top surface the body portion of the conductive pattern.

5. The semiconductor device of claim 3, wherein a level of top surface of the edge portion of the conductive pattern is higher than a top surface of the body portion of the conductive pattern.

6. The semiconductor device of claim 1, further comprising:
an inner spacer between the source/drain pattern and the gate electrode, wherein
the insulating structure in the substrate is one insulating structure among a plurality of insulating structures in the substrate, and a surface of the inner spacer, a surface of insulating structure, and a surface of the back-side gate contact define a void between the inner spacer and the back-side gate contact.

7. The semiconductor device of claim 1, wherein a surface of the insulating structure is convex toward the source/drain pattern.

8. The semiconductor device of claim 1, wherein
the insulating structure comprises a basal dielectric pattern and a liner layer on the basal dielectric pattern,
the liner layer extends along a first side surface of the basal dielectric pattern over a top surface of the basal dielectric pattern to a second side surface of the basal dielectric pattern.

9. The semiconductor device of claim 1, further comprising:
a gate insulating layer between the gate electrode and the channel pattern;
a gate spacer on a side surface of the gate electrode;
a first interlayer insulating layer covering the source/drain pattern;
an active contact penetrating the first interlayer insulating layer, the active contact being electrically connected to the source/drain pattern;
a first metal layer on the first interlayer insulating layer; and
a second metal layer on the first metal layer.

10. The semiconductor device of claim 1, wherein
the back-side metal layer comprises a backside interconnection line, and
the backside interconnection line and the back-side gate contact are electrically connected to each other through a backside via.

11. A semiconductor device, comprising:
a substrate including a plurality of insulating structures;
a back-side metal layer below the substrate;
a source/drain pattern on each of the plurality of insulating structures;
a channel pattern connected to the source/drain pattern, the channel pattern including a first semiconductor pattern, a second semiconductor pattern, and a third semiconductor pattern, which are vertically stacked and spaced apart from each other;
a gate electrode on the first semiconductor pattern to the third semiconductor pattern,
the gate electrode including a first inner electrode, a second inner electrode, and a third inner electrode, the second inner electrode and the third inner electrode being between adjacent semiconductor patterns among the first semiconductor pattern, the second semiconductor pattern, and the third semiconductor pattern, and
the gate electrode including an outer electrode on the third semiconductor pattern;
an inner spacer separating the source/drain pattern and the gate electrode from each other;
a back-side gate contact penetrating the substrate and extending between the plurality of insulating structures; and
an air gap pattern between the back-side gate contact and the inner spacer, wherein
the air gap pattern is enclosed by the insulating structure, the inner spacer, the first inner electrode, and the back-side gate contact.

12. The semiconductor device of claim 11, wherein the air gap pattern comprises a void.

13. The semiconductor device of claim 11, wherein a bottom surface of the inner spacer is at a higher level than a bottom surface of the first inner electrode.

14. The semiconductor device of claim 11, wherein
the back-side gate contact comprises a conductive pattern and a barrier pattern on the conductive pattern, and
a portion of the barrier pattern is in contact with the first inner electrode.

15. The semiconductor device of claim 11, further comprising:
a gate insulating layer between the first inner electrode and the inner spacer, wherein
the gate insulating layer is between the first inner electrode and the first semiconductor pattern, and
the air gap pattern is enclosed by one of the plurality of insulating structures, the inner spacer, the gate insulating layer, the first inner electrode, and the back-side gate contact.

16. The semiconductor device of claim 11, wherein the air gap pattern is a void that is shaped like a seam or a slit.

17. The semiconductor device of claim 16, wherein a width of the air gap pattern in a first direction decreases as a level of the air gap pattern decreases vertically downward toward the substrate.

18. A semiconductor device, comprising:
a substrate including a plurality of insulating structures;
a source/drain pattern on each of the insulating structures;
a channel pattern connected to the source/drain pattern, the channel pattern including a plurality of semiconductor patterns, which are stacked and spaced apart from each other;
a gate electrode on the channel pattern;
a gate insulating layer between the gate electrode and the channel pattern;
a gate spacer on a side surface of the gate electrode;
a first interlayer insulating layer covering the source/drain pattern and the gate electrode;
an active contact penetrating the first interlayer insulating layer, the active contact being electrically connected to the source/drain pattern;
a first metal layer on the first interlayer insulating layer, the first metal layer including a first interconnection line electrically connected to the active contact;
a second metal layer on the first metal layer, the second metal layer including a second interconnection line electrically connected to the first metal layer;
a back-side metal layer below the substrate; and
a back-side gate contact penetrating the substrate and electrically connecting the back-side metal layer to the gate electrode, wherein
the gate electrode includes a first inner electrode, a second inner electrode, and a third inner electrode, the second inner electrode and the third inner electrode being between adjacent semiconductor patterns among the plurality of semiconductor patterns,
the gate electrode includes an outer electrode on an uppermost one of the plurality of semiconductor patterns,
the first inner electrode has a first thickness, the second inner electrode has a second thickness, the third inner electrode has a third thickness, and the outer electrode has a fourth thickness,
the first thickness is equal to or larger than the fourth thickness.

19. The semiconductor device of claim 18, wherein
the second thickness, the third thickness, and the fourth thickness are equal to each other, and
the first thickness is 2.5 to 3.5 times the fourth thickness.

20. The semiconductor device of claim 18, wherein
the back-side gate contact comprises a first surface and a second surface,
the first surface of the back-side gate contact is in contact with a bottom surface of the gate electrode; and
the second surface of the back-side gate contact in contact with a side surface of the insulating structure, and
an angle between the first of the back-side gate contact and the second surface of the back-side gate contact ranges from 45° to 90°.
